(19) United States
(12) Patent Application Publication
(10) Pub. No.: US 2025/0167163 A1
(43) Pub. Date: May 22, 2025

(54) SEMICONDUCTOR DEVICE

(71) Applicant: Rohm Co., Ltd., Kyoto-shi (JP)

(72) Inventor: Kazunori FUJI, Kyoto-shi (JP)

(21) Appl. No.: 19/027,703

(22) Filed: Jan. 17, 2025

Related U.S. Application Data
(63) Continuation of application No. PCT/JP2023/023728, filed on Jun. 27, 2023.

(30) Foreign Application Priority Data
Jul. 22, 2022 (JP) 2022-117163

(51) Int. Cl. H01L 23/00; H01L 23/373; H01L 23/538; H01L 25/07

(52) U.S. Cl. CPC H01L 24/32; H01L 23/3735; H01L 23/5385; H01L 24/48; H01L 24/73; H01L 25/072; H01L 2224/2612; H01L 2224/32225; H01L 2224/48227; H01L 2224/73215; H01L 2224/73265

(57) ABSTRACT

A semiconductor device includes a first insulation layer, a first conductive layer, a second conductive layer, a first heat dissipation layer, a first semiconductor element, a second semiconductor element, a conductive member, and a sealing resin. The first heat dissipation layer is located opposite from the first conductive layer and the second conductive layer with respect to the first insulation layer. The first semiconductor element includes a first electrode conductively bonded to the first conductive layer, and a second electrode to which conductive the member is conductively bonded. The second semiconductor element includes a third electrode conductively bonded to the conductive member, and a fourth electrode conductively bonded to the second conductive layer. A polarity of the second electrode is different from a polarity of the third electrode. The first heat dissipation layer and the conductive member are exposed from the sealing resin.

### TECHNICAL FIELD

The present disclosure relates to a semiconductor device.

### BACKGROUND ART

Conventionally, a semiconductor device provided with a semiconductor element having a switching function has been widely known. Such a semiconductor device is mainly used for power conversion. JP-A-2013-258387 discloses an example of such a semiconductor device.

The semiconductor element in the semiconductor device disclosed in JP-A-2013-258387 has a source electrode and a drain electrode located opposite to each other. A top plate electrode is conductively bonded to the source electrode. A drain electrode pattern is conductively bonded to the drain electrode. The semiconductor element is located between the top plate electrode and the drain electrode pattern. Such a configuration can reduce the parasitic inductance in the semiconductor device while achieving downsizing of the semiconductor device. However, the area of the source electrode is generally smaller than that of the drain electrode. Thus, in the semiconductor device, the amount of heat dissipated from the source electrode to the top plate electrode is smaller than the amount of heat dissipated from the drain electrode to the drain electrode pattern, resulting in insufficient heat dissipation of the semiconductor element.

### BRIEF DESCRIPTION OF THE DRAWINGS

FIG. 1 is a plan view showing a semiconductor device according to a first embodiment of the present disclosure.

FIG. 2 is a plan view corresponding to FIG. 1, with a sealing resin as well as a second insulation layer and a second heat dissipation layer of a conductive member shown as transparent.

FIG. 3 is a plan view corresponding to FIG. 2, with a third conductive layer of the conductive member also shown as transparent.

FIG. 4 is a bottom view showing the semiconductor device in FIG. 1.

FIG. 5 is a cross-sectional view taken along line V-V in FIG. 2.

FIG. 6 is a cross-sectional view taken along line VI-VI in FIG. 2.

FIG. 7 is a cross-sectional view taken along line VII-VII in FIG. 2.

FIG. 8 is a cross-sectional view taken along line VIII-VIII in FIG. 2.

FIG. 9 is a partially enlarged view of FIG. 3, showing a first semiconductor element and its neighboring area, with the first semiconductor element shown as transparent.

FIG. 10 is a cross-sectional view taken along line X-X in FIG. 9.

FIG. 11 is a cross-sectional view taken along line XI-XI in FIG. 9.

FIG. 12 is a partially enlarged view of FIG. 3, showing a second semiconductor element and its neighboring area.

FIG. 13 is a cross-sectional view taken along line XIII-XIII in FIG. 12.

FIG. 14 is a plan view showing a semiconductor device according to a second embodiment of the present disclosure, with a sealing resin as well as a second insulation layer and a second heat dissipation layer of a conductive member shown as transparent.

FIG. 15 is a plan view corresponding to FIG. 14, with a third conductive layer of the conductive member also shown as transparent.

FIG. 16 is a cross-sectional view taken along line XVI-XVI in FIG. 14.

FIG. 17 is a cross-sectional view taken along line XVII-XVII in FIG. 14.

FIG. 18 is a cross-sectional view taken along line XVIII-XVIII in FIG. 14.

FIG. 19 is a cross-sectional view taken along line XIX-XIX in FIG. 14.

FIG. 20 is a plan view showing a first semiconductor element of the semiconductor device in FIG. 14.

FIG. 21 is a bottom view showing the first semiconductor element in FIG. 20.

FIG. 22 is a cross-sectional view taken along line XXII-XXII in FIG. 20.

FIG. 23 is a cross-sectional view taken along line XXIII-XXIII in FIG. 20.

FIG. 24 is a cross-sectional view taken along line XXIV-XXIV in FIG. 20.

FIG. 25 is a cross-sectional view taken along line XXV-XXV in FIG. 20.

FIG. 26 is a partially enlarged view of FIG. 15, showing the first semiconductor element and its neighboring area.

FIG. 27 is a cross-sectional view taken along line XXVII-XXVII in FIG. 26.

FIG. 28 is a plan view showing a second semiconductor element of the semiconductor device in FIG. 14.

FIG. 29 is a bottom view showing the second semiconductor element in FIG. 28.

FIG. 30 is a cross-sectional view taken along line XXX-XXX in FIG. 28.

FIG. 31 is a cross-sectional view taken along line XXXI-XXXI in FIG. 28.

FIG. 32 is a cross-sectional view taken along line XXXII-XXXII in FIG. 28.

FIG. 33 is a partially enlarged view of FIG. 15, showing the second semiconductor element and its neighboring area.

FIG. 34 is a cross-sectional view taken along line XXXIV-XXXIV in FIG. 33.

FIG. 35 is a plan view showing a semiconductor device according to a third embodiment of the present disclosure, with a sealing resin and a covering layer shown as transparent.

FIG. 36 is a cross-sectional view taken along line XXXVI-XXXVI in FIG. 35.

FIG. 37 is a cross-sectional view taken along line XXXVII-XXXVII in FIG. 35.

### DETAILED DESCRIPTION OF EMBODIMENTS

Embodiments of the present disclosure will be described with reference to the accompanying drawings.

### First Embodiment

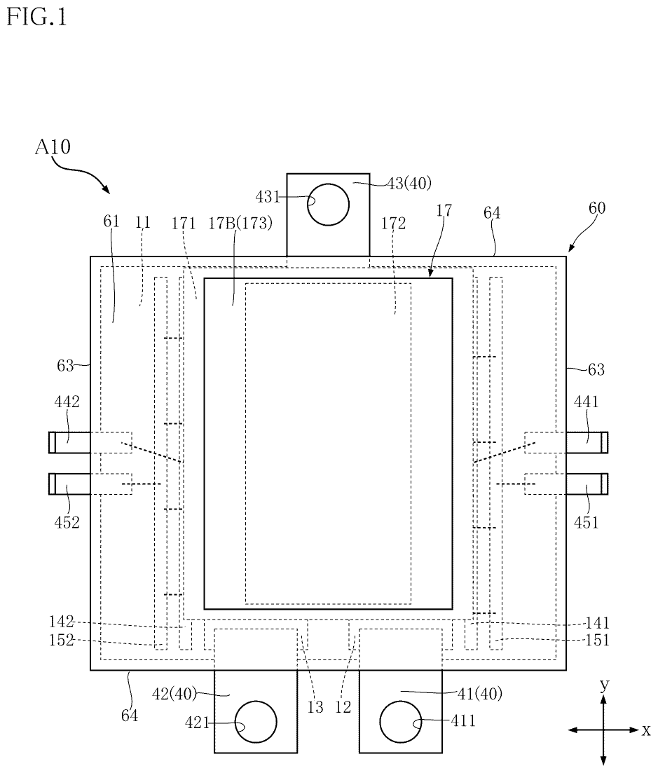

The following describes a semiconductor device A10 of a first embodiment of the present disclosure with reference to FIGS. 1 to 13. The semiconductor device A10 includes a first insulation layer 11, a first conductive layer 12, a second conductive layer 13, a first heat dissipation layer 16, a conductive member 17, a plurality of first semiconductor elements 21, a plurality of second semiconductor elements 22, a plurality of first spacers 31, a plurality of second spacers 32, a plurality of power terminals 40, and a sealing resin 60. The semiconductor device A10 further includes a first gate conductive layer 141, a second gate conductive layer 142, a first detection conductive layer 151, a second detection conductive layer 152, a first gate terminal 441, a second gate terminal 442, a first detection terminal 451, and a second detection terminal 452.

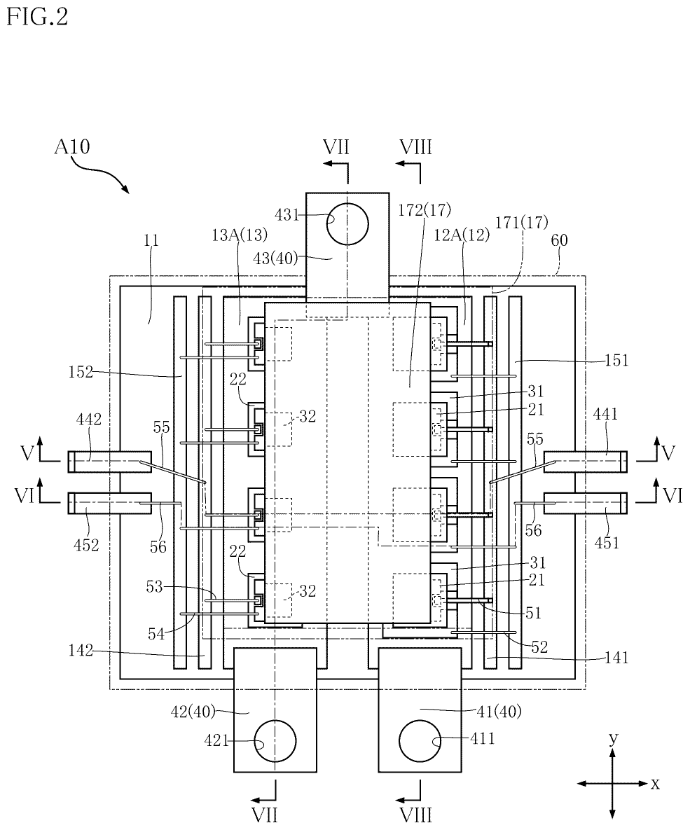

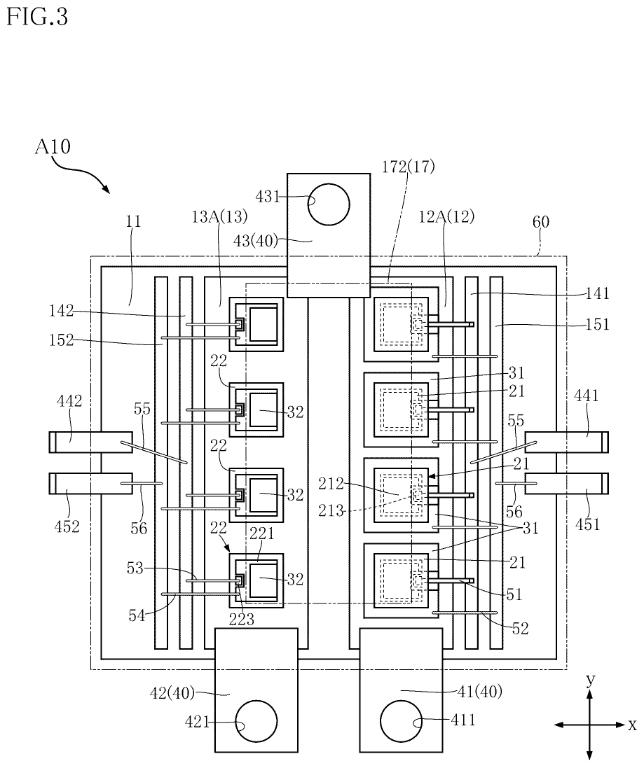

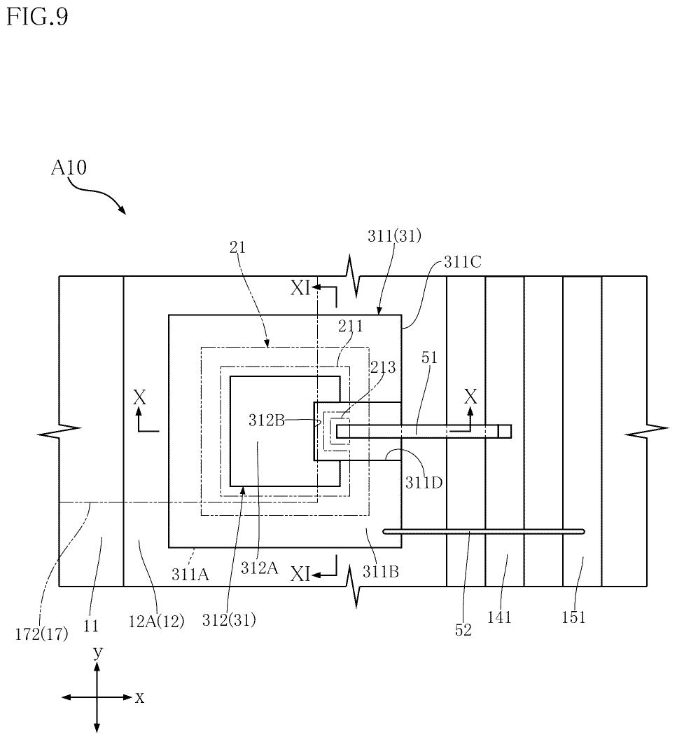

For convenience of understanding, FIG. 2 shows the sealing resin 60 as well as a second insulation layer 171 and a second heat dissipation layer 173 (described below) of the conductive member 17 as transparent. For convenience of understanding, FIG. 3 also shows a third conductive layer 172 (described below) of the conductive member 17 in FIG. 2 as transparent. For convenience of understanding, FIG. 9 also shows a first semiconductor element 21 in FIG. 3 as transparent. In FIGS. 2 and 3, the outline of the sealing resin 60, which is shown as transparent, is indicated by an imaginary line (two-dot chain line). In FIGS. 2 and 3, the outline of the elements of the conductive member 17, which are shown as transparent, are indicated by imaginary lines. FIG. 9 shows the first semiconductor element 21 as transparent, where the first semiconductor element 21 is indicated by an imaginary line. In FIG. 2, line V-V, line VI-VI, and line VII-VII are indicated by single-dot chain lines.

In the description of the semiconductor device A10, the normal direction of a first obverse surface 12A (described below) of the first conductive layer 12 is referred to as a “first direction z” for convenience. A direction perpendicular to the first direction z is referred to as a “second direction x”. The direction perpendicular to the first direction z and the second direction x is referred to as a “third direction y”.

The semiconductor device A10 uses the first semiconductor elements 21 and the second semiconductor elements 22 to convert the DC source voltage applied to a first input terminal 41 and a second input terminal 42 (described below) among the power terminals 40 into AC power. The AC power obtained by the conversion is inputted from an output terminal 43 (described below) among the power terminals 40 to a power-supply target such as a motor. The semiconductor device A10 forms a part of a power conversion circuit such as an inverter.

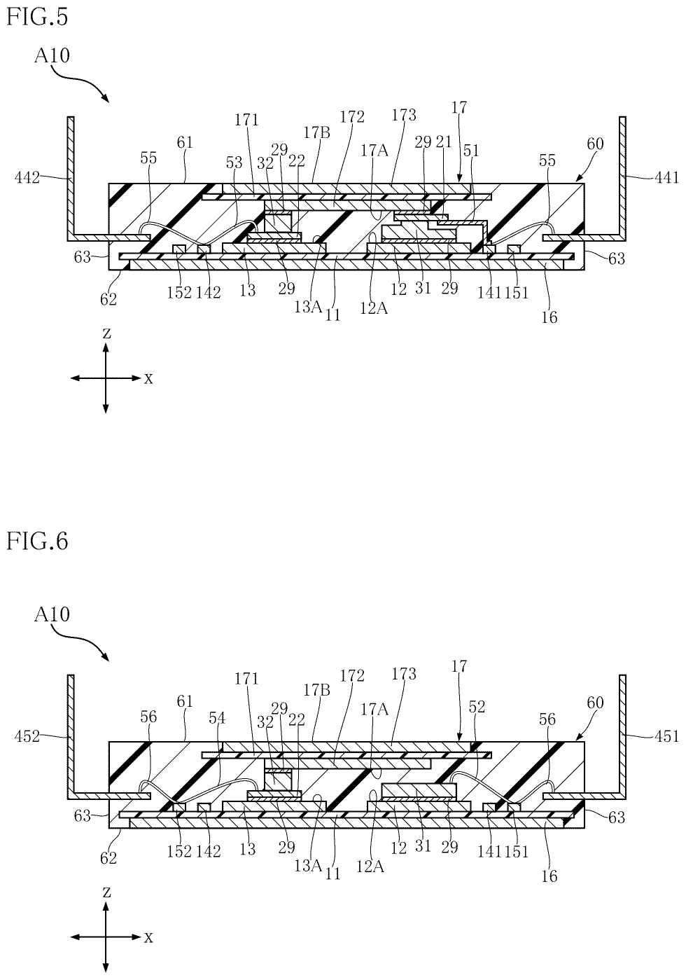

As shown in FIGS. 5 and 6, the first insulation layer 11 supports the first conductive layer 12, the second conductive layer 13, the first gate conductive layer 141, the second gate conductive layer 142, the first detection conductive layer 151, the second detection conductive layer 152, and the first heat dissipation layer 16. The first insulation layer 11 is made of a material having a relatively high thermal conductivity. The first insulation layer 11 is made of a ceramic material containing aluminum nitride (AlN), for example. The periphery of the first insulation layer 11 is enclosed in the sealing resin 60 in the first direction z. The thickness of the first insulation layer 11 is smaller than the thickness of each of the first conductive layer 12, the second conductive layer 13, and the first heat dissipation layer 16. Thus, in the semiconductor device A10, the thickness of each of the first conductive layer 12, the second conductive layer 13, and the first heat dissipation layer 16 is larger than the thickness of the first insulation layer 11.

As shown in FIGS. 2, 3, 5, 6 and 8, the first conductive layer 12 is bonded to the first insulation layer 11 on a first side in the first direction z. The first semiconductor elements 21 and the first spacers 31 are mounted on the first conductive layer 12. The first conductive layer 12 has a rectangular shape elongated in the third direction y. As viewed in the first direction z, the first conductive layer 12 is surrounded by the periphery of the first insulation layer 11. The composition of the first conductive layer 12 includes copper (Cu). The first conductive layer 12 has a first obverse surface 12A facing in the first direction z. The first semiconductor elements 21 and the first spacers 31 face the first obverse surface 12A.

As shown in FIGS. 2, 3, and 5 to 7, the second conductive layer 13 is located on the same side as the first conductive layer 12 in the first direction z, and is bonded to the first insulation layer 11. The second semiconductor elements 22 are mounted on the second conductive layer 13. The second conductive layer 13 is spaced apart from the first conductive layer 12 in the second direction x. The second conductive layer 13 has a rectangular shape elongated in the third direction y. As viewed in the first direction z, the second conductive layer 13 is surrounded by the periphery of the first insulation layer 11. The composition of the second conductive layer 13 includes copper. The second conductive layer 13 has a second obverse surface 13A facing the same side as the first obverse surface 12A of the first conductive layer 12 in the first direction z. The second semiconductor elements 22 face the second obverse surface 13A.

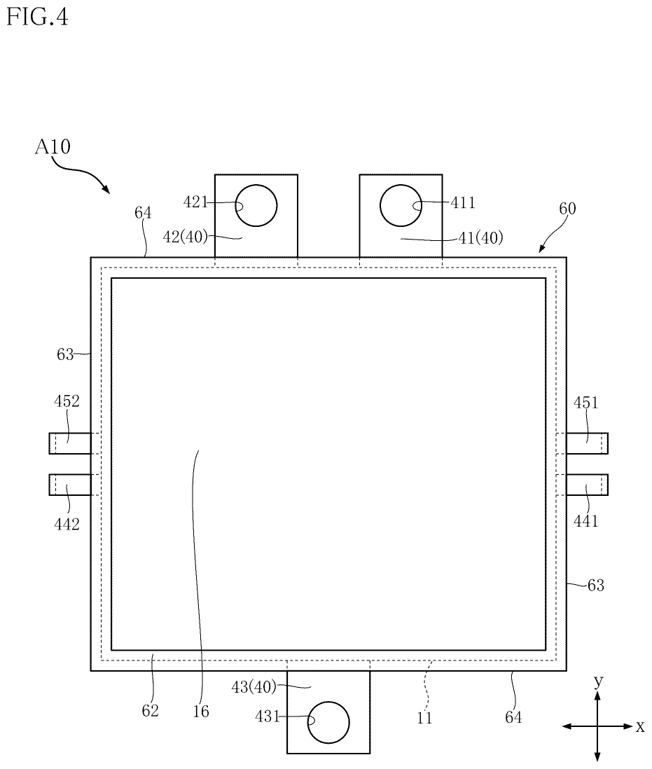

As shown in FIGS. 5 to 8, the first heat dissipation layer 16 is located opposite from the first conductive layer 12 and the second conductive layer 13 with respect to the first insulation layer 11, and is bonded to the first insulation layer 11. The first heat dissipation layer 16 is exposed from the sealing resin 60. The volume of the first heat dissipation layer 16 is larger than the sum of the volumes of the first conductive layer 12 and the second conductive layer 13. As shown in FIG. 4, the first heat dissipation layer 16 is surrounded by the periphery of the first insulation layer 11 as viewed in the first direction z. The composition of the first heat dissipation layer 16 includes copper. When the semiconductor device A10 is used, a heat sink (not shown) is bonded to the first heat dissipation layer 16.

As shown in FIGS. 5 and 8, the first semiconductor elements 21 are bonded to the first spacers 31. The first semiconductor elements 21 are identical to each other. The first semiconductor elements 21 are MOSFETS (Metal-Oxide-Semiconductor Field-Effect Transistors), for example. Alternatively, the first semiconductor elements 21 may be field effect transistors including MISFETs (Metal-Insulator-Semiconductor Field-Effect Transistors) or bipolar transistors such as IGBTS (Insulated Gate Bipolar Transistors). In the description of the semiconductor device A10, each of the first semiconductor elements 21 is an n-channel type MOSFET with a vertical structure. Each of the first semiconductor elements 21 includes a compound semiconductor substrate. The composition of the compound semiconductor substrate includes silicon carbide (Sic). The first semiconductor elements 21 are aligned in the third direction y.

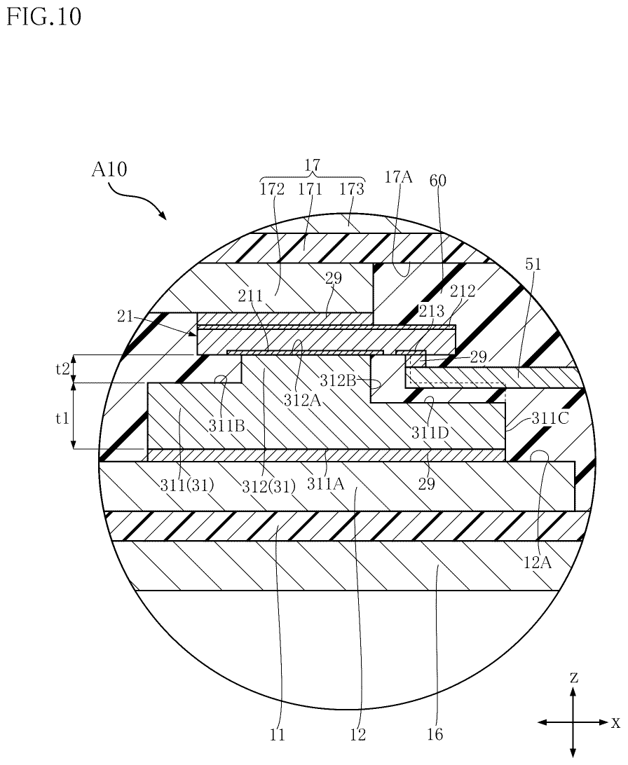

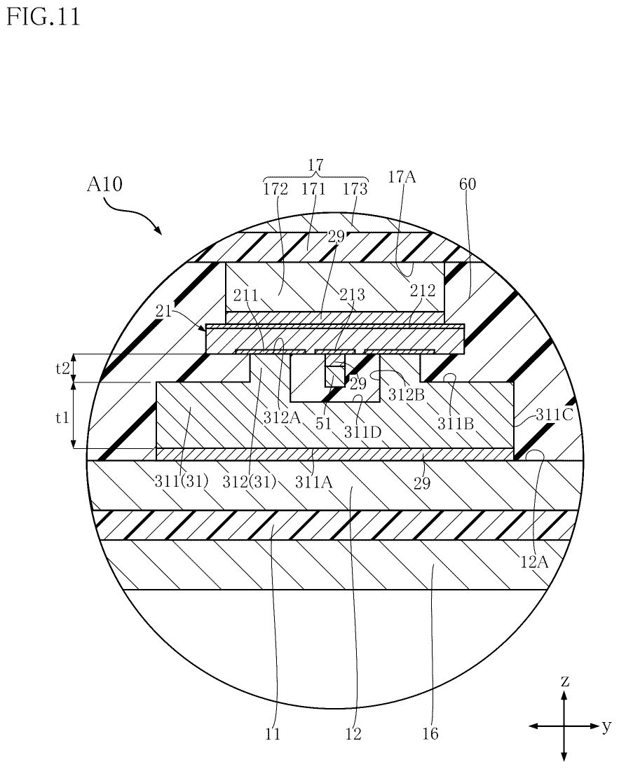

As shown in FIGS. 10 and 11, each of the first semiconductor elements 21 has a first electrode 211, a second electrode 212, and a first gate electrode 213.

As shown in FIGS. 10 and 11, the first electrode 211 faces the first obverse surface 12A of the first conductive layer 12. The current flowing through the first electrode 211 corresponds to the electric power that has been converted by the first semiconductor element 21. In other words, the first electrode 211 corresponds to the source electrode of the first semiconductor element 21.

As shown in FIGS. 10 and 11, the second electrode 212 is located opposite from the side facing the first obverse surface 12A of the first conductive layer 12 in the first direction z. The current flowing through the second electrode 212 corresponds to the electric power that has yet to be converted by the first semiconductor element 21. In other words, the second electrode 212 corresponds to the drain electrode of the first semiconductor element 21.

As shown in FIGS. 10 and 11, the first gate electrode 213 faces the first obverse surface 12A of the first conductive layer 12. Thus, the first gate electrode 213 is located on the same side as the first electrode 211 in the first direction z. A gate voltage for driving the first semiconductor element 21 is applied to the first gate electrode 213. As shown in FIG. 9, the area of the first gate electrode 213 is smaller than that of the first electrode 211 as viewed in the first direction z.

As shown in FIGS. 5 to 7, the second semiconductor elements 22 are bonded to the second obverse surface 13A of the second conductive layer 13. The second semiconductor elements 22 are identical to the first semiconductor elements 21. Thus, each of the second semiconductor elements 22 is an n-channel type MOSFET with a vertical structure. The second semiconductor elements 22 are aligned in the third direction y.

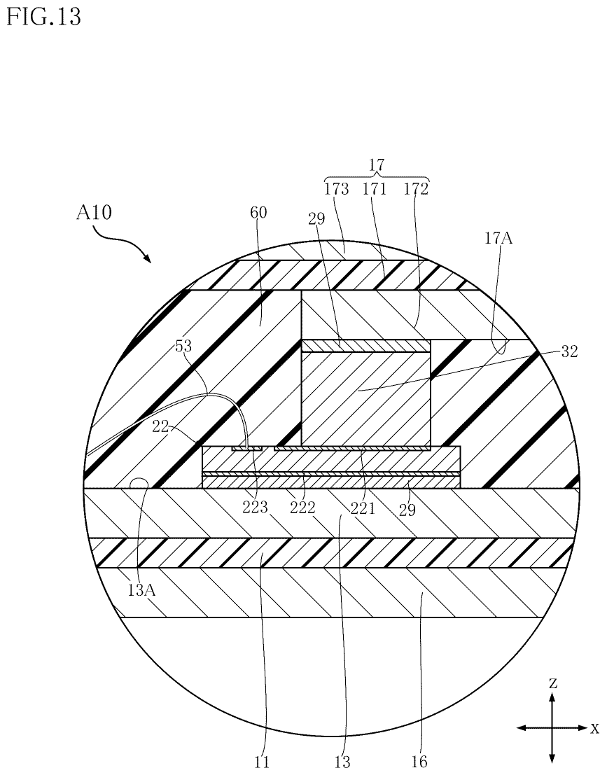

As shown in FIG. 13, each of the second semiconductor elements 22 has a third electrode 221, a fourth electrode 222, and a second gate electrode 223.

As shown in FIG. 13, the third electrode 221 is located opposite from the side facing the second obverse surface 13A of the second conductive layer 13 in the first direction z. The current flowing through the third electrode 221 corresponds to the electric power that has been converted by the second semiconductor element 22. In other words, the third electrode 221 corresponds to the source electrode of the second semiconductor element 22.

As shown in FIG. 13, the fourth electrode 222 faces the second obverse surface 13A of the second conductive layer 13. The current flowing through the fourth electrode 222 corresponds to the electric power that has yet to be converted by the second semiconductor element 22. In other words, the fourth electrode 222 corresponds to the drain electrode of the second semiconductor element 22. The fourth electrode 222 is conductively bonded to the second obverse surface 13A via a conductive bonding layer 29. This allows the fourth electrodes 222 of the second semiconductor elements 22 to be electrically connected to the second conductive layer 13. The conductive bonding layer 29 is solder, for example. Alternatively, the conductive bonding layer 29 may be a sintered metal containing silver (Ag), for example.

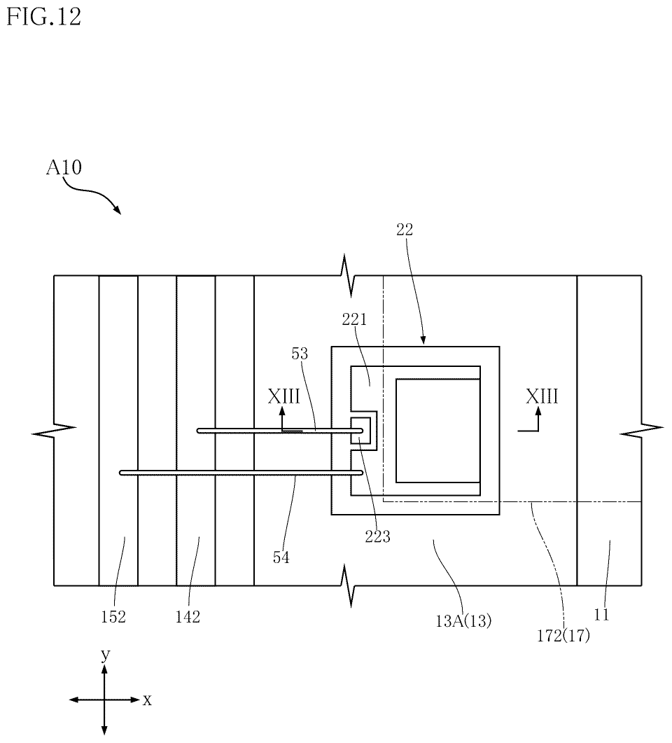

As shown in FIG. 13, the second gate electrode 223 is located opposite from the side facing the second obverse surface 13A of the second conductive layer 13 in the first direction z. Thus, the second gate electrode 223 is located on the same side as the third electrode 221 in the first direction z. A gate voltage for driving the second semiconductor element 22 is applied to the second gate electrode 223. As shown in FIG. 12, the area of the second gate electrode 223 is smaller than that of the third electrode 221 as viewed in the first direction z.

In the semiconductor device A10, the first semiconductor elements 21 form a part of an upper arm circuit, and the second semiconductor elements 22 form a part of a lower arm circuit. In the semiconductor device A10, the first semiconductor elements 21 have the same configuration as the second semiconductor elements 22 when the second semiconductor elements 22 are inverted about a direction perpendicular to the first direction z. Thus, the polarity of the first electrode 211 of each first semiconductor element 21 is different from the polarity of the fourth electrode 222 of each second semiconductor element 22. In addition, the second electrode 212 of each first semiconductor element 21 is different from the third electrode 221 of each second semiconductor element 22.

As shown in FIG. 8, the first spacers 31 are conductively bonded to the first obverse surface 12A of the first conductive layer 12. As shown in FIGS. 8, 10, and 11, the first electrode 211 of each first semiconductor element 21 is conductively bonded to one of the first spacers 31. Thus, each of the first spacers 31 conductively bonds the first conductive layer 12 and the first electrode 211 of one of the first semiconductor elements 21. The first electrode 211 of each first semiconductor element 21 is electrically connected to one of the first spacers 31, and is conductively bonded to the first conductive layer 12 via the first spacer 31. The first spacers 31 are aligned in the third direction y. The first spacers 31 are located between the first obverse surface 12A and the first semiconductor elements 21. As shown in FIGS. 10 and 11, each of the first spacers 31 includes a first portion 311 and a second portion 312. As shown in FIG. 9, each of the first spacers 31 has a rectangular shape as viewed in the first direction z. Alternatively, each of the first spacers 31 may have a circular shape as viewed in the first direction z. The composition of the first spacers 31 includes copper.

As shown in FIGS. 9 to 11, the first portion 311 has a second surface 311A, a third surface 311B, and a fourth surface 311C. The second surface 311A faces the first obverse surface 12A of the first conductive layer 12. The second surface 311A is conductively bonded to the first obverse surface 12A via a conductive bonding layer 29. Alternatively, the second surface 311A may be conductively bonded to the first obverse surface 12A by solid phase diffusion. The third surface 311B faces away from the second surface 311A in the first direction z. As viewed in the first direction z, the first semiconductor elements 21 is surrounded by the periphery of the third surface 311B. The fourth surface 311C faces in directions perpendicular to the first direction z. In the semiconductor device A10, the fourth surface 311C includes a plurality of areas.

As shown in FIGS. 9 to 11, the first portion 311 is provided with a first recess 311D recessed from the third surface 311B and the fourth surface 311C. As viewed in the first direction z, the first gate electrode 213 of the first semiconductor element 21 overlaps with the first recess 311D.

As shown in FIGS. 10 and 11, the second portion 312 is located between the first portion 311 and the first electrode 211 of the first semiconductor element 21. The second portion 312 is connected to the first portion 311 at the third surface 311B. As shown in FIG. 9, the second portion 312 is surrounded by the periphery of the first semiconductor element 21 as viewed in the first direction z. As viewed in the first direction z, the second portion 312 is spaced apart from the first gate electrode 213 of the first semiconductor element 21.

A dimension t1 of the first portion 311 in the first direction z is larger than a dimension t2 of the second portion 312 in the first direction z. The dimension t1 is 3 to 30 times greater than the dimension t2.

As shown in FIGS. 9 to 11, the second portion 312 has a first surface 312A. The first surface 312A faces the first semiconductor element 21. As viewed in the first direction z, the first surface 312A is spaced apart from the first gate electrode 213 of the first semiconductor element 21. As viewed in the first direction z, the first surface 312A is surrounded by the periphery of the second surface 311A of the first portion 311. In the semiconductor device A10, the area of the first surface 312A is smaller than that of the first electrode 211 of the first semiconductor element 21. The first electrode 211 of each first semiconductor element 21 is conductively bonded to the first surface 312A of one of the first spacers 31 by solid phase diffusion. Alternatively, the first electrode 211 of each first semiconductor element 21 may be conductively bonded to the first surface 312A of one of the first spacers 31 via a conductive bonding layer 29.

As shown in FIGS. 9 to 11, the second portion 312 is provided with a second recess 312B recessed in a direction perpendicular to the first direction z. The second recess 312B penetrates through the second portion 312 in the first direction z, and is connected to the first recess 311D of the first portion 311. As viewed in the first direction z, the second recess 312B overlaps with the first recess 311D and the first gate electrode 213 of the first semiconductor element 21.

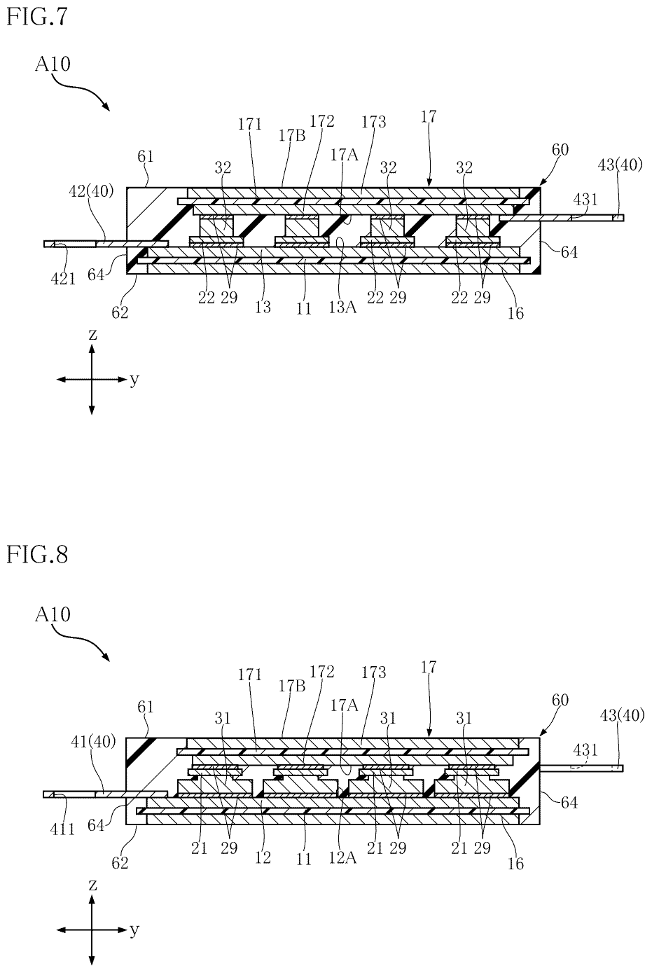

As shown in FIGS. 7 and 13, the second spacers 32 are conductively bonded to the third electrodes 221 of the respective second semiconductor elements 22. The second spacers 32 are aligned in the third direction y. The second spacers 32 are located between the second semiconductor elements 22 and the conductive member 17. As shown in FIG. 12, each of the second spacers 32 has a rectangular shape as viewed in the first direction z. Alternatively, each of the second spacers 32 may have a circular shape as viewed in the first direction z. As viewed in the first direction z, the area of each of the second spacers 32 is smaller than that of each of the third electrodes 221. The composition of the second spacers 32 includes copper. The second spacers 32 are conductively bonded to the third electrodes 221 of the respective second semiconductor elements 22 by solid phase diffusion. Alternatively, each of the second spacers 32 may be conductively bonded to the third electrode 221 of a second semiconductor element 22 via a conductive bonding layer 29.

As shown in FIGS. 2, 3, 5, and 6, the first gate conductive layer 141 is located on the same side as the first conductive layer 12 in the first direction z, and is bonded to the first insulation layer 11. The first gate conductive layer 141 is located opposite from the second conductive layer 13 with respect to the first conductive layer 12. The first gate conductive layer 141 extends in the third direction y. The composition of the first gate conductive layer 141 includes copper.

As shown in FIGS. 2 and 3, the first gate terminal 441 is located opposite from the first conductive layer 12 with respect to the first gate conductive layer 141 in the second direction x. The first gate terminal 441 is electrically connected to the first gate conductive layer 141. The first gate terminal 441 is a metal lead made of a material containing copper or a copper alloy. As shown in FIGS. 1 and 5, a portion of the first gate terminal 441 is covered with the sealing resin 60. The first gate terminal 441 has an L shape as viewed in the third direction y. As shown in FIG. 5, the first gate terminal 441 includes a portion standing in the first direction z. The standing portion is exposed from the sealing resin 60. A gate voltage for driving the first semiconductor elements 21 is applied to the first gate terminal 441.

FIG. 9 shows a plurality of first gate wirings 51, each of which is conductively bonded to the first gate electrode 213 of one of the first semiconductor elements 21 and the first gate conductive layer 141. This allows the first gate electrodes 213 of the first semiconductor elements 21 to be electrically connected to the first gate conductive layer 141. The first gate wirings 51 are metal leads. The composition of the first gate wirings 51 includes copper.

As shown in FIGS. 2, 3, 5, and 6, the second gate conductive layer 142 is located on the same side as the second conductive layer 13 in the first direction z, and is bonded to the first insulation layer 11. The second gate conductive layer 142 is located opposite from the first gate conductive layer 141 with respect to the first conductive layer 12 and the second conductive layer 13 in the second direction x. The second gate conductive layer 142 extends in the third direction y. The composition of the second gate conductive layer 142 includes copper.

As shown in FIGS. 2 and 3, the second gate terminal 442 is located opposite from the second conductive layer 13 with respect to the second gate conductive layer 142 in the second direction x. The second gate terminal 442 is electrically connected to the second gate conductive layer 142. The second gate terminal 442 is a metal lead made of a material containing copper or a copper alloy. As shown in FIGS. 1 and 5, a portion of the second gate terminal 442 is covered with the sealing resin 60. The second gate terminal 442 has an L shape as viewed in the third direction y. As shown in FIG. 5, the second gate terminal 442 includes a portion standing in the first direction z. The standing portion is exposed from the sealing resin 60. A gate voltage for driving the second semiconductor elements 22 is applied to the second gate terminal 442.

FIG. 12 shows a plurality of second gate wirings 53, each of which is conductively bonded to the second gate electrode 223 of one of the second semiconductor elements 22 and the second gate conductive layer 142. This allows the second gate electrodes 223 of the second semiconductor elements 22 to be electrically connected to the second gate conductive layer 142. The second gate wirings 53 are wires. The composition of the second gate wirings 53 includes gold (Au). Alternatively, the composition of the second gate wirings 53 may include copper or aluminum.

As shown in FIG. 2, the semiconductor device A10 further includes two first wires 55. As shown in FIGS. 2 and 5, each of the two first wires 55 is bonded to the first gate terminal 441 or the second gate terminal 442 and to the first gate conductive layer 141 or the second gate conductive layer 142. This allows the first gate terminal 441 to be electrically connected to the first gate conductive layer 141, and also allows the second gate terminal 442 to be electrically connected to the second gate conductive layer 142. The composition of the two first wires 55 includes gold. Alternatively, the composition of the two first wires 55 may include copper or aluminum.

As shown in FIGS. 2, 3, 5, and 6, the first detection conductive layer 151 is located on the same side as the second conductive layer 13 in the first direction z, and is bonded to the first insulation layer 11. The first detection conductive layer 151 is located next to the first gate conductive layer 141 in the second direction x. The first detection conductive layer 151 extends in the third direction y. The composition of the first detection conductive layer 151 includes copper.

As shown in FIGS. 2 and 3, the first detection terminal 451 is located opposite from the first conductive layer 12 with respect to the first detection conductive layer 151 in the second direction x. The first detection terminal 451 is located next to the first gate terminal 441 in the third direction y. The first detection terminal 451 is electrically connected to the first detection conductive layer 151. The first detection terminal 451 is a metal lead made of a material containing copper or a copper alloy. As shown in FIGS. 1 and 6, a portion of the first detection terminal 451 is covered with the sealing resin 60. The first detection terminal 451 has an L shape as viewed in the third direction y. As shown in FIG. 6, the first detection terminal 451 includes a portion standing in the first direction z. The standing portion is exposed from the sealing resin 60. A voltage having the same potential as the voltage applied to the first electrode 211 of each first semiconductor element 21 is applied to the first detection terminal 451.

As shown in FIG. 9, each of first detection wirings 52 is conductively bonded to the third surface 311B of one of the first spacers 31 and the first detection conductive layer 151. This allows the first electrodes 211 of the first semiconductor elements 21 to be electrically connected to the first detection conductive layer 151. The first detection wirings 52 are wires. The composition of the first detection wirings 52 includes gold. Alternatively, the composition of the first detection wirings 52 may include copper or aluminum.

As shown in FIGS. 2, 3, 5, and 6, the second detection conductive layer 152 is located on the same side as the second conductive layer 13 in the first direction z, and is bonded to the first insulation layer 11. The second detection conductive layer 152 is located next to the second gate conductive layer 142 in the second direction x. The second detection conductive layer 152 extends in the third direction y. The composition of the second detection conductive layer 152 includes copper.

As shown in FIGS. 2 and 3, the second detection terminal 452 is located opposite from the second conductive layer 13 with respect to the second detection conductive layer 152 in the second direction x. The second detection terminal 452 is located next to the second gate terminal 442 in the third direction y. The second detection terminal 452 is electrically connected to the second detection conductive layer 152. The second detection terminal 452 is a metal lead made of a material containing copper or a copper alloy. As shown in FIGS. 1 and 6, a portion of the second detection terminal 452 is covered with the sealing resin 60. The second detection terminal 452 has an L shape as viewed in the third direction y. As shown in FIG. 6, the second detection terminal 452 includes a portion standing in the first direction z. The standing portion is exposed from the sealing resin 60. A voltage having the same potential as the voltage applied to the third electrode 221 of each second semiconductor element 22 is applied to the second detection terminal 452.

FIG. 12 shows a plurality of second detection wirings 54, each of which is conductively bonded to the third electrode 221 of one of the second semiconductor elements 22 and the second detection conductive layer 152. This allows the third electrodes 221 of the second semiconductor elements 22 to be electrically connected to the second detection conductive layer 152. The second detection wirings 54 are wires. The composition of the second detection wirings 54 includes gold. Alternatively, the composition of the second detection wirings 54 may include copper or aluminum.

As shown in FIG. 2, the semiconductor device A10 further includes two second wires 56. As shown in FIGS. 2 and 6, each of the two second wires 56 is bonded to the first detection terminal 451 or the second detection terminal 452, and to the first detection conductive layer 151 or the second detection conductive layer 152. This allows the first detection terminal 451 to be electrically connected to the first detection conductive layer 151, and also allows the second detection terminal 452 to be electrically connected to the second detection conductive layer 152. The composition of the two second wires 56 includes gold. Alternatively, the composition of the two second wires 56 may include copper or aluminum.

As shown in FIGS. 5 to 8, the conductive member 17 is spaced apart from the first insulation layer 11 to the side that the first obverse surface 12A of the first conductive layer 12 faces in the first direction z. The conductive member 17 is conductively bonded to the second electrode 212 of each first semiconductor element 21 and the third electrode 221 of each second semiconductor element 22. The conductive member 17 is exposed from the sealing resin 60.

As shown in FIGS. 5 to 8, the conductive member 17 has a bonding surface 17A and a heat dissipation surface 17B. The bonding surface 17A is conductively bonded to the second electrodes 212 of each first semiconductor element 21 via a conductive bonding layer 29. The bonding surface 17A is also conductively bonded to the third electrode 221 of each second semiconductor element 22 via a conductive bonding layer 29 and a second spacer 32. The heat dissipation surface 17B faces away from the bonding surface 17A in the first direction z. The heat dissipation surface 17B is exposed from the sealing resin 60. As viewed in the first direction z, the bonding surface 17A is surrounded by the periphery of the heat dissipation surface 17B. The area of the heat dissipation surface 17B is larger than that of the bonding surface 17A.

As shown in FIGS. 5 to 8, the conductive member 17 has a second insulation layer 171, a third conductive layer 172, and a second heat dissipation layer 173. The material of the second insulation layer 171 contains the material of the first insulation layer 11. The third conductive layer 172 includes the bonding surface 17A, and is bonded to the second insulation layer 171. The material of the third conductive layer contains the material of each of the first conductive layer 12 and the second conductive layer 13. The second heat dissipation layer 173 includes the heat dissipation surface 17B, and is bonded to the second insulation layer 171. The material of the second heat dissipation layer 173 contains the material of the first heat dissipation layer 16. As shown in FIG. 1, the second heat dissipation layer 173 is surrounded by the periphery of the second insulation layer 171 as viewed in the first direction z. The thickness of each of the third conductive layer 172 and the second heat dissipation layer 173 is larger than the thickness of the second insulation layer 171.

As shown in FIGS. 2, 5, and 6, the first gate wirings 51, the first detection wirings 52, the second gate wirings 53, and the second detection wirings 54 overlap with each of the second insulation layer 171 and the second heat dissipation layer 173, as viewed in the first direction z.

As shown in FIGS. 7 and 8, each of the power terminals 40 is conductively bonded to one of the first conductive layer 12, the second conductive layer 13, and the third conductive layer 172 of the conductive member 17. The power terminals 40 include a first input terminal 41, a second input terminal 42, and an output terminal 43.

As shown in FIGS. 1 to 3, the first input terminal 41 is located on a first side in the third direction y with respect to the first insulation layer 11. As shown in FIG. 8, the first input terminal 41 is conductively bonded to the first conductive layer 12. This allows the first input terminal 41 to be electrically connected to the first electrodes 211 of the first semiconductor elements 21 via the first conductive layer 12 and the first spacers 31. The first input terminal 41 is a metal plate made of a material containing copper or a copper alloy. A portion of the first input terminal 41 is covered with the sealing resin 60. The first input terminal 41 has a first mounting hole 411 penetrating in the first direction z. The first mounting hole 411 is spaced apart from the sealing resin 60. The first input terminal 41 is an N terminal (negative electrode) to which the DC source voltage targeted for power conversion is applied.

As shown in FIGS. 1 to 3, the second input terminal 42 is located on the same side as the first input terminal 41 with respect to the first insulation layer 11 in the third direction y. The second input terminal 42 is spaced apart from the first input terminal 41 in the second direction x. As shown in FIG. 7, the second input terminal 42 is conductively bonded to the second conductive layer 13. This allows the second input terminal 42 to be electrically connected to the fourth electrodes 222 of the second semiconductor elements 22 via the second conductive layer 13. The second input terminal 42 is a metal plate made of a material containing copper or a copper alloy. A portion of the second input terminal 42 is covered with the sealing resin 60. The second input terminal 42 has a second mounting hole 421 penetrating in the first direction z. The second mounting hole 421 is spaced apart from the sealing resin 60. The second input terminal 42 is a P terminal (positive electrode) to which the DC source voltage targeted for power conversion is applied.

As shown in FIGS. 1 and 2, the output terminal 43 is located opposite from the first input terminal 41 and the second input terminal 42 with respect to the first insulation layer 11 in the third direction y. As shown in FIG. 7, the output terminal 43 is spaced apart from the first insulation layer 11 to the side that the first obverse surface 12A of the first conductive layer 12 faces in the first direction z. The output terminal 43 is conductively bonded to the third conductive layer 172 of the conductive member 17. This allows the output terminal 43 to be electrically connected to the second electrodes 212 of the first semiconductor elements 21 and the third electrodes 221 of the second semiconductor elements 22 via the conductive member 17. The output terminal 43 is a metal plate made of a material containing copper or a copper alloy. A portion of the output terminal 43 is covered with the sealing resin 60. The output terminal 43 has a third mounting hole 431 penetrating in the first direction z. The third mounting hole 431 is spaced apart from the sealing resin 60. The output terminal 43 outputs the AC power converted by the first semiconductor elements 21 and the second semiconductor elements 22.

As shown in FIGS. 5 to 8, the sealing resin 60 covers the first semiconductor elements 21 and the second semiconductor elements 22. The sealing resin 60 is an insulator. The sealing resin 60 is made of a material containing a black epoxy resin, for example. A portion of the sealing resin 60 is located between the first insulation layer 11 and the third conductive layer 172 of the conductive member 17 in the first direction z.

As shown in FIGS. 1, 4, and 5 to 8, the sealing resin 60 has a top surface 61, a bottom surface 62, two first side surfaces 63, and two second side surfaces 64. The top surface 61 faces the same side as the first obverse surface 12A of the first conductive layer 12 in the first direction z. The heat dissipation surface 17B of the conductive member 17 is exposed from the top surface 61. The bottom surface 62 faces away from the top surface 61 in the first direction z. The first heat dissipation layer 16 is exposed from the bottom surface 62.

As shown in FIGS. 1, and 4 to 6, the two first side surfaces 63 are spaced apart from each other in the second direction x and connected to the top surface 61 and the bottom surface 62. The first gate terminal 441 and the first detection terminal 451 are exposed from one of the two first side surfaces 63. The second gate terminal 442 and the second detection terminal 452 are exposed from the other one of the two first side surfaces 63.

As shown in FIGS. 1, 4, 7, and 8, the two second side surfaces 64 are spaced apart from each other in the third direction y and connected to the top surface 61 and the bottom surface 62. The first input terminal 41 and the second input terminal 42 are exposed from one of the two second side surfaces 64. The output terminal 43 is exposed from the other one of the two second side surfaces 64.

The following describes advantages of the semiconductor device A10.

The semiconductor device A10 includes a first insulation layer 11, a first conductive layer 12, a second conductive layer 13, a first heat dissipation layer 16, a first semiconductor element 21, a second semiconductor element 22, a conductive member 17, and a sealing resin 60. The first semiconductor element 21 has a first t electrode 211 conductively bonded to the first conductive layer 12, and a second electrode 212 to which the conductive member 17 is conductively bonded. The second semiconductor element 22 has a third electrode 221 to which the conductive member 17 is conductively bonded, and a fourth electrode 222 conductively bonded to the second conductive layer 13. The polarity of the second electrode 212 is different from that of the third electrode 221. The first heat dissipation layer 16 and the conductive member 17 are exposed from the sealing resin 60. This configuration shortens the length of a conductive path from the second electrode 212 to the third electrode 221. This makes it possible to reduce the parasitic inductance of the semiconductor device A10. In addition, this configuration releases the heat generated by the first semiconductor element 21 and the second semiconductor element 22 to the outside via the first heat dissipation layer 16 and the conductive member 17 which are located on the respective sides of the semiconductor device A10 in the first direction z. Thus, according to the configuration, it is possible to improve the heat dissipation of the semiconductor device A10 while reducing the parasitic inductance of the semiconductor device A10.

The conductive member 17 has a bonding surface 17A and a heat dissipation surface 17B. The bonding surface 17A is conductively bonded to the second electrode 212 of the first semiconductor element 21 and the third electrode 221 of the second semiconductor element 22. The heat dissipation surface 17B is exposed from the sealing resin 60. The area of the heat dissipation surface 17B is larger than that of the bonding surface 17A. As viewed in the first direction z, the bonding surface 17A is surrounded by the periphery of the heat dissipation surface 17B. With this configuration, the heat conducted from the first semiconductor element 21 and the second semiconductor element 22 to the bonding surface 17A is easily diffused in a direction perpendicular to the first direction z. This makes it possible to reduce the heat resistance of the conductive member 17 in the first direction Z.

The conductive member 17 has a second insulation layer 171, a third conductive layer 172 including the bonding surface 17A and bonded to the second insulation layer 171, and a second heat dissipation layer 173 including the heat dissipation surface 17B and bonded to the second insulation layer 171. This configuration electrically insulates the conductive member 17 from the outside of the semiconductor device A10 even if the conductive member 17 is exposed from the sealing resin 60. As viewed in the first direction z, the second heat dissipation layer 173 is surrounded by the periphery of the second insulation layer 171. With this configuration, when the conductive member 17 is about to fall off the sealing resin 60, the periphery of the second insulation layer 171 makes contact with the sealing resin 60 in the first direction z, thereby preventing fall of the conductive member 17.

The thickness of each of the third conductive layer 172 and the second heat dissipation layer 173 is larger than the thickness of the second insulation layer 171. This configuration improves the heat diffusion efficiency in each of the third conductive layer 172 and the second heat dissipation layer 173 in a direction perpendicular to the first direction z. This further improves the heat dissipation of the semiconductor device A10.

In the semiconductor device A10, a first gate electrode 213 of the first semiconductor element 21 is located on the same side as the first electrode 211 of the first semiconductor element 21 in the first direction z. The semiconductor device A10 further includes a first spacer 31 that conductively bonds the first conductive layer 12 and the first electrode 211. The first spacer 31 has a first surface 312A that faces the first electrode 211. As viewed in the first direction z, the first surface 312A is spaced apart from the first gate electrode 213. This configuration can prevent the first gate electrode 213 and a first gate wiring 51 shown in FIG. 10 from having a short circuit with the first spacer 31.

The first spacer 31 has a second surface 311A that faces the first conductive layer 12. The area of the second surface 311A is larger than that of the first surface 312A. As viewed in the first direction z, the first surface 312A is surrounded by the periphery of the second surface 311A. Suppose here that the first spacer 31 is designed to have a virtual plane extending from the periphery of the first surface 312A to the second surface 311A and forming an inclination angle of 45° with respect to the first direction z. In this case, the heat conducted to the first spacer 31 is diffused uniformly in the area surrounded by the virtual plane. Thus, in the present embodiment, the configuration described above is employed so that the heat conducted from the first surface 312A to the first spacer 31 is more likely to be diffused uniformly in the first direction z as well as in a direction perpendicular to the first direction z. As a result, the heat conducted from the first electrode 211 of the first semiconductor element 21 to the first spacer 31 is more promptly conducted to the first conductive layer 12.

The thickness of each of the first conductive layer 12, the second conductive layer 13, and the first heat dissipation layer 16 is larger than that of the first insulation layer 11. This configuration improves the heat diffusion efficiency in each of the first conductive layer 12, the second conductive layer 13, and the first heat dissipation layer 16 in a direction perpendicular to the first direction z. This further improves the heat dissipation of the semiconductor device A10.

### Second Embodiment

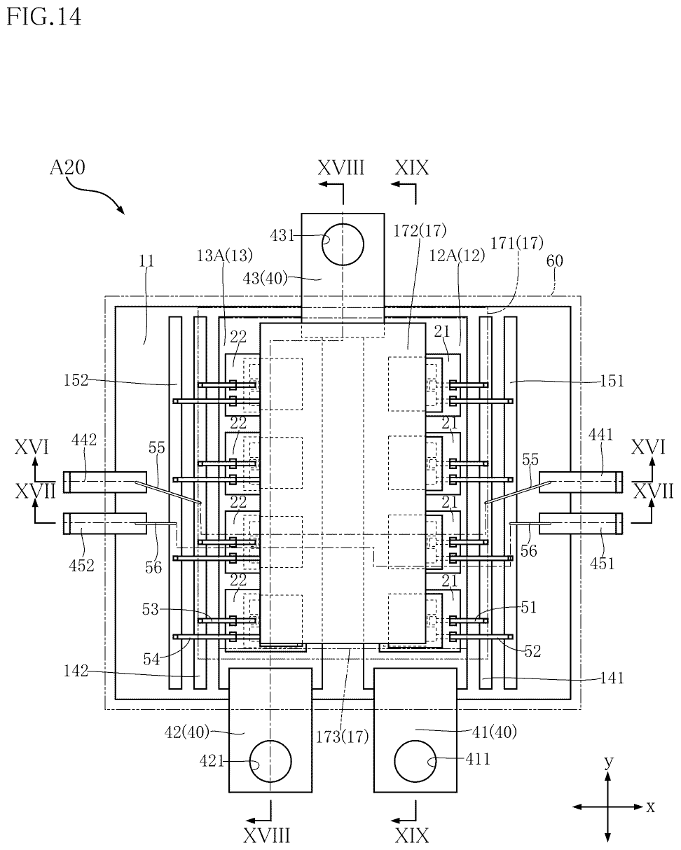

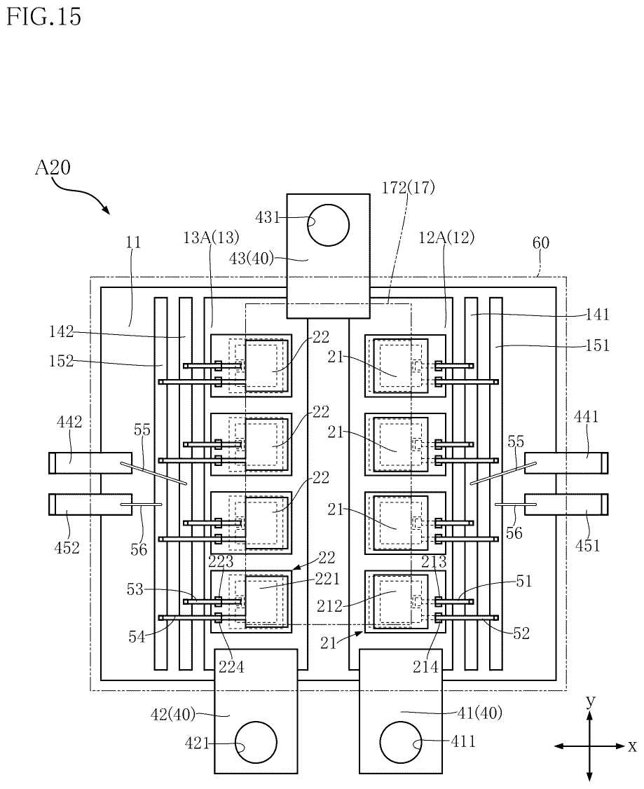

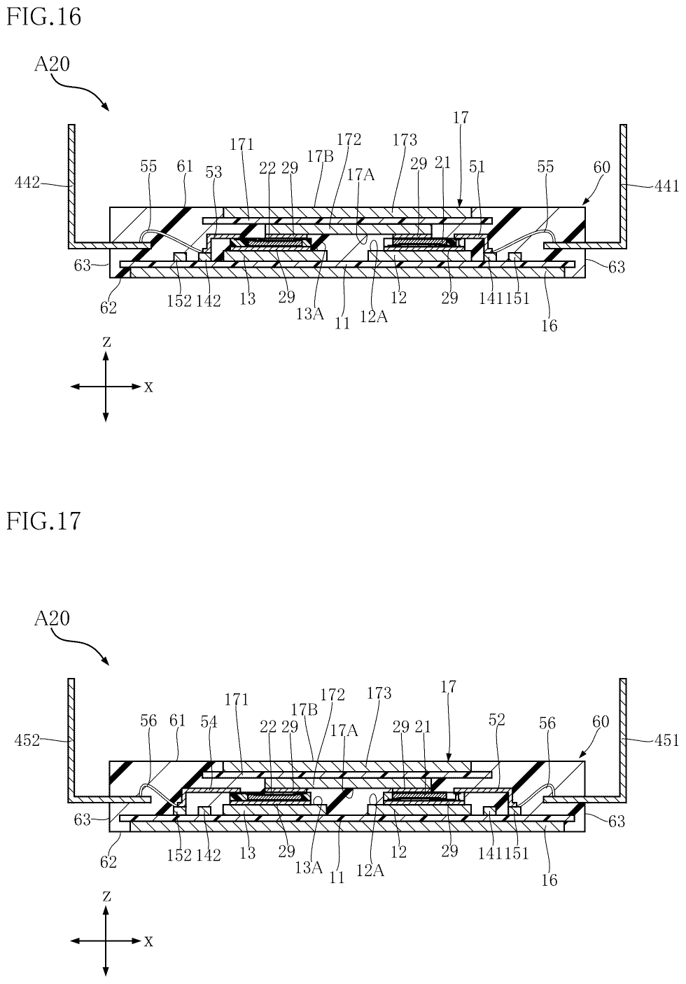

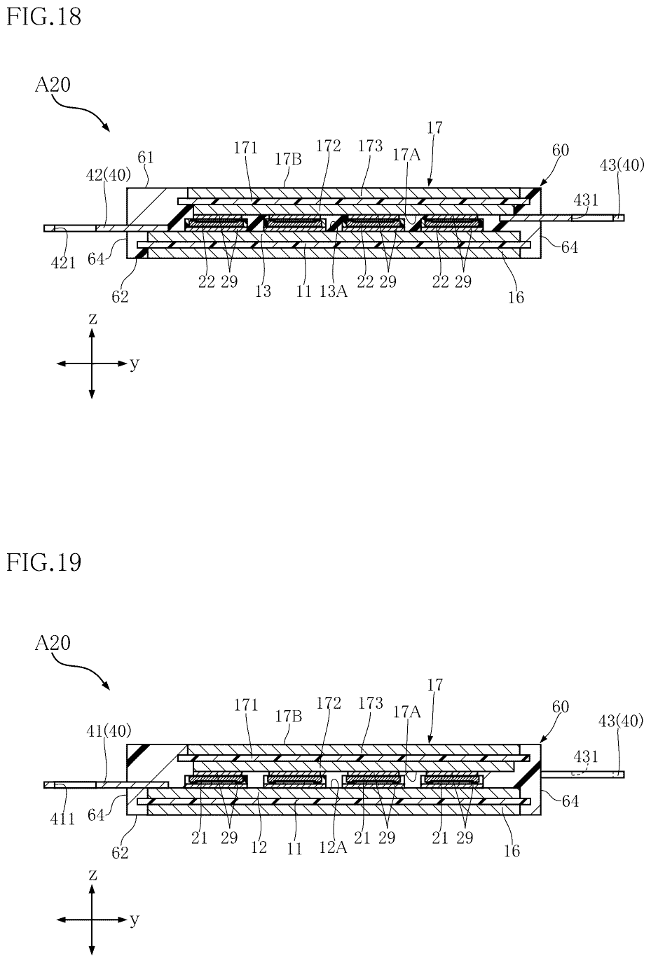

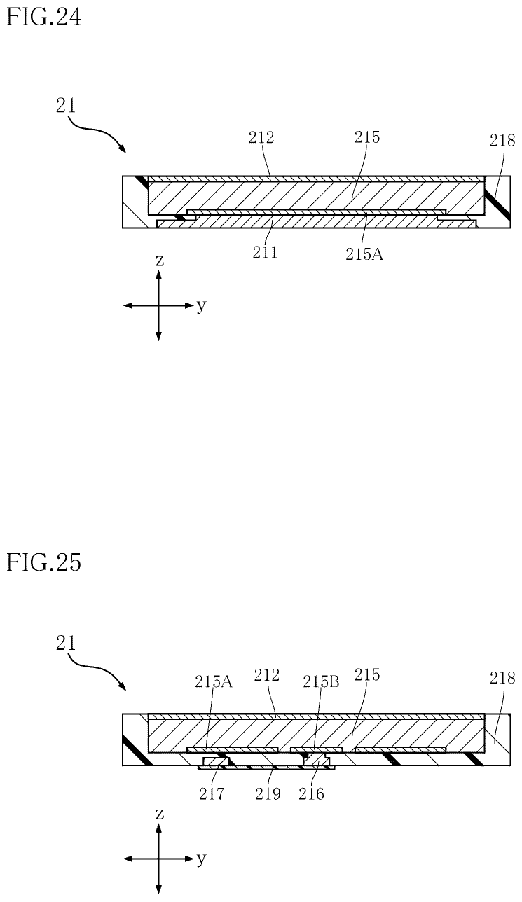

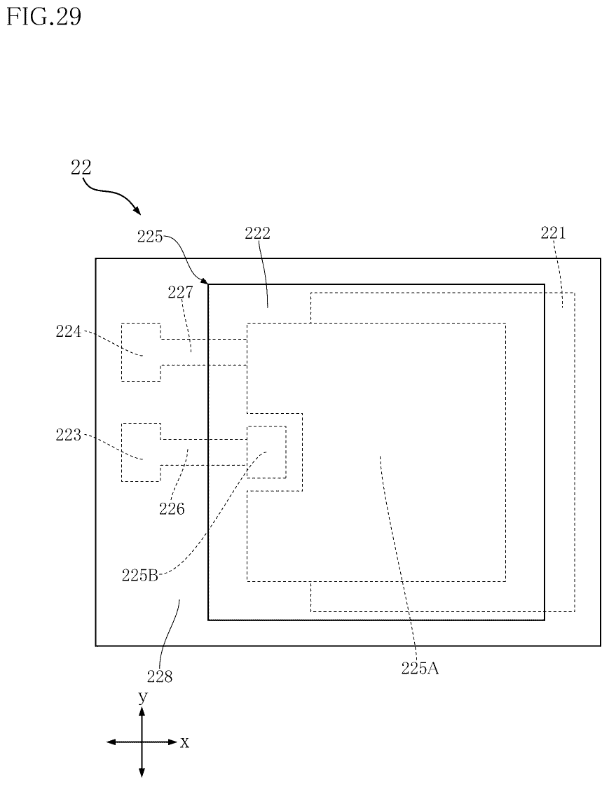

The following describes a semiconductor device A20 of a second embodiment of the present disclosure with reference to FIGS. 14 to 34. In these figures, elements that are the same as or similar to those of the semiconductor device A10 are denoted by the same reference numerals and the descriptions thereof are omitted. For convenience of understanding, FIG. 14 shows the sealing resin 60 as well as the second insulation layer 171 and the second heat dissipation layer 173 of the conductive member 17 as transparent. For convenience of understanding, FIG. 15 also shows the third conductive layer 172 of the conductive member 17 in FIG. 14 as transparent. In FIGS. 14 and 15, the outline of the sealing resin 60, which is shown as transparent, is indicated by an imaginary line. In FIGS. 14 and 15, the outline of the elements of the conductive member 17, which are shown as transparent, are indicated by imaginary lines. FIG. 14 shows lines XVI-XVI, XVII-XVII, and XVIII-XVIII with single-dot chain lines.

The semiconductor device A20 is different from the semiconductor device A10 in the configurations of the first semiconductor elements 21 and the second semiconductor elements 22, and in not including the first spacers 31 or the second spacers 32.

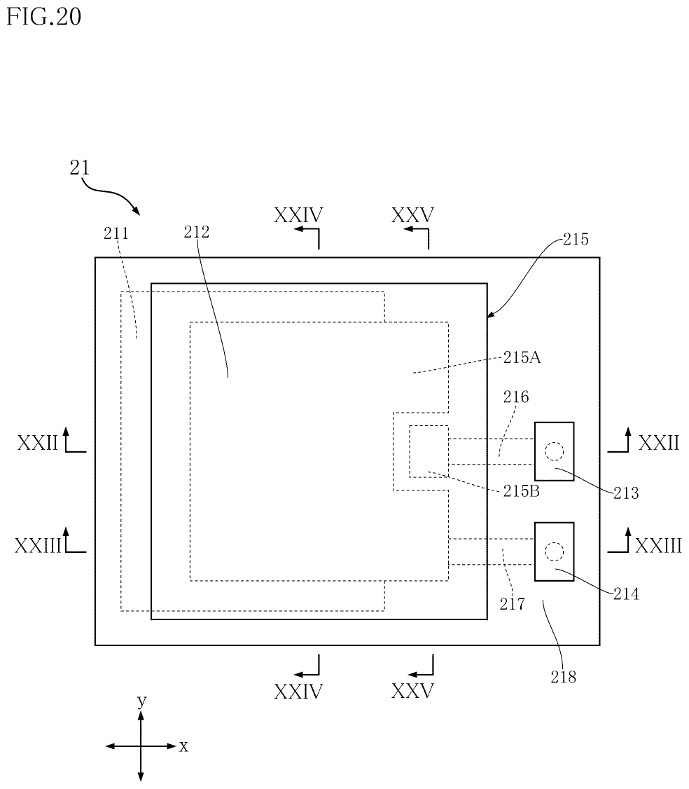

As shown in FIGS. 20 to 25, each of the first semiconductor elements 21 has a first detection electrode 214, a first element body 215, a first rewiring 216, a second rewiring 217, a first resin 218, and a covering layer 219. Each of the first semiconductor elements 21 is provided in a resin package.

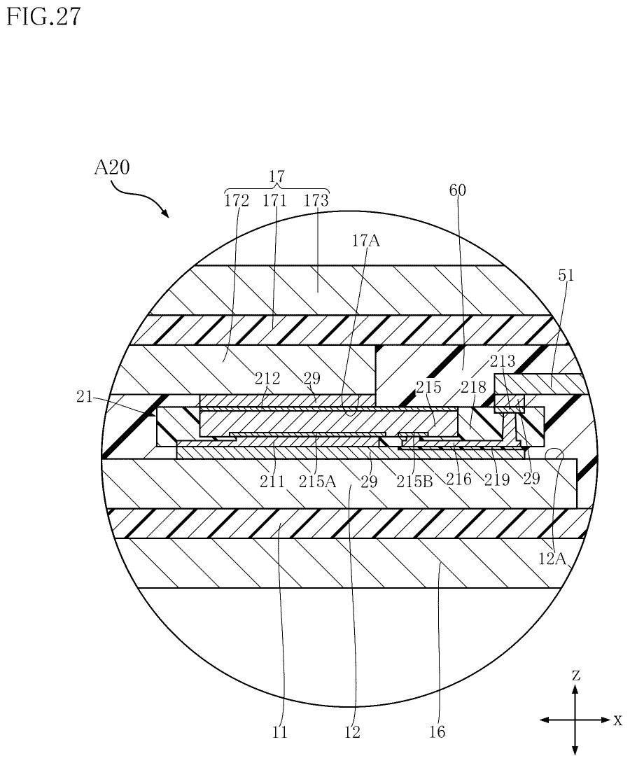

The first element body 215 is an element corresponding to one of the first semiconductor elements 21 in the semiconductor device A10. The first element body 215 includes a first pad 215A and a first gate pad 215B. As shown in FIG. 27, the first pad 215A and the first gate pad 215B are located on the side facing the first conductive layer 12 in the first direction z. The first pad 215A corresponds to the first electrode 211 of the first semiconductor element 21 in the semiconductor device A10. The first gate pad 215B corresponds to the first gate electrode 213 of the first semiconductor element 21 in the semiconductor device A10. The first element body 215 includes a second electrode 212.

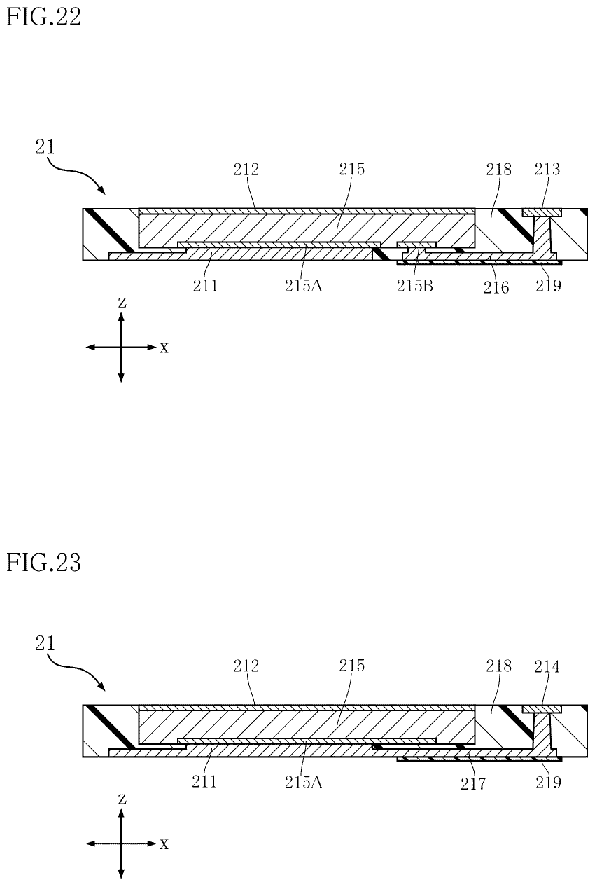

As shown in FIGS. 22 to 25, the first resin 218 covers a portion of the first element body 215 and at least a portion of each of the first rewiring 216 and the second rewiring 217. The first electrode 211, the second electrode 212, the first gate electrode 213, and the first detection electrode 214 are exposed from the first resin 218.

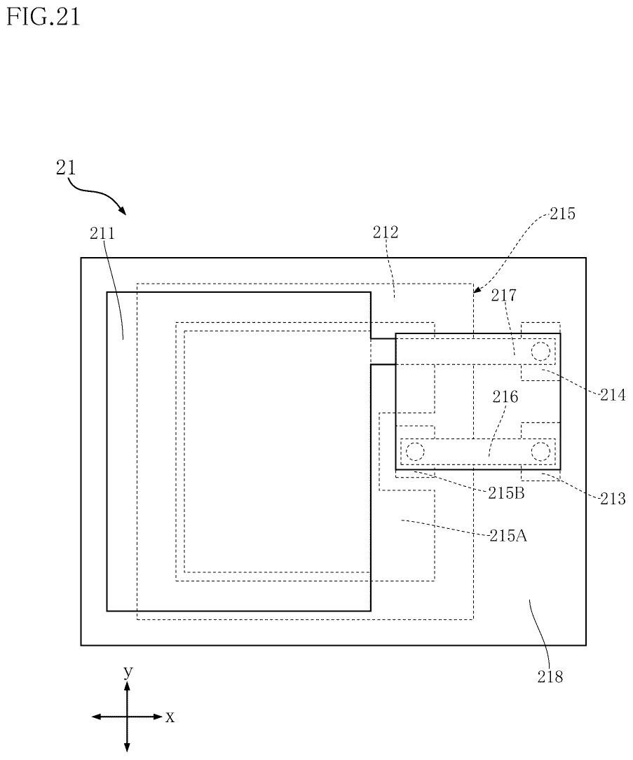

As shown in FIGS. 22 to 24, the first electrode 211 is electrically connected to and in contact with the first pad 215A of the first element body 215. As shown in FIG. 21, the first electrode 211 includes a portion extending outward beyond the second electrode 212 as viewed in the first direction z. As viewed in the first direction z, the area of the first electrode 211 is larger than that of the first pad 215A.

As shown in FIGS. 20, 22, and 23, the first gate electrode 213 and the first detection electrode 214 are located on the same side as the second electrode 212 in the first direction z. The first detection electrode 214 is spaced apart from the first gate electrode 213 in the third direction y.

As shown in FIGS. 20 to 22, the first rewiring 216 electrically connects the first gate pad 215B of the first element body 215 and the first gate electrode 213. A portion of the first rewiring 216 is covered with the first resin 218.

As shown in FIGS. 20, 21, and 23, the second rewiring 217 electrically connects the first pad 215A of the first element body 215 and the first detection electrode 214. A portion of the second rewiring 217 is covered with the first resin 218. The second rewiring 217 is connected to the first electrode 211.

The first rewiring 216, the second rewiring 217, and the first resin 218 can be formed by a laser direct structuring (LDS) process disclosed in U.S. Publication No. 2010/0019370, for example. In this case, the material of the first resin 218 contains an additive containing a metal element. Each of the first rewiring 216 and the second rewiring 217 contains the metal element.

As shown in FIGS. 21 to 23, the covering layer 219 covers a portion of each of the first rewiring 216 and the second rewiring 217 that are exposed from the first resin 218. The covering layer 219 is an insulator. The covering layer 219 is in contact with the first rewiring 216, the second rewiring 217, and the first resin 218. The covering layer 219 is solder resist, for example.

As shown in FIG. 27, the bonding surface 17A of the third conductive layer 172 of the conductive member 17 is conductively bonded to the second electrode 212 of each of the first semiconductor elements 21 via a conductive bonding layer 29.

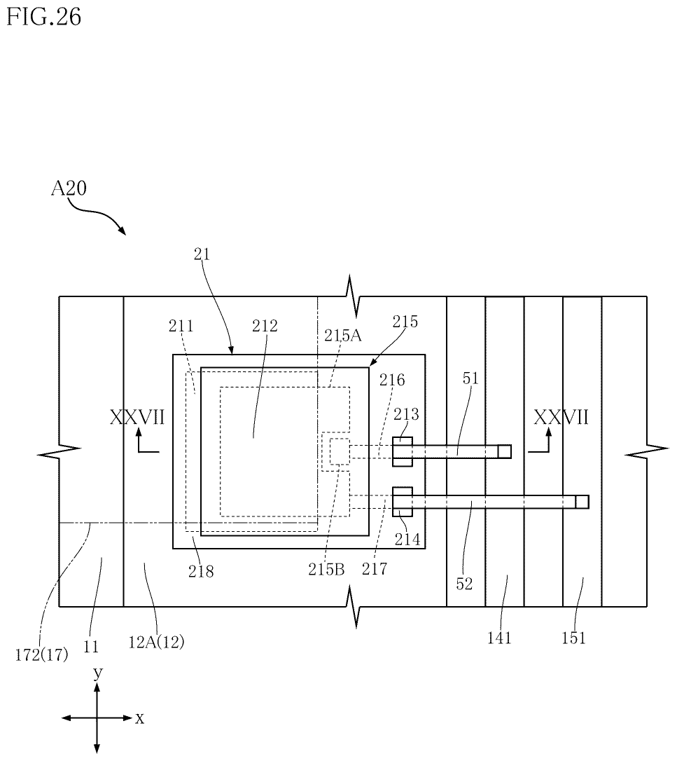

As shown in FIGS. 15 and 26, each of the first detection wirings 52 is conductively bonded to the first detection electrode 214 of one of the first semiconductor elements 21 and the first detection conductive layer 151. The first detection wirings 52 are metal leads. The composition of the first detection wirings 52 includes copper.

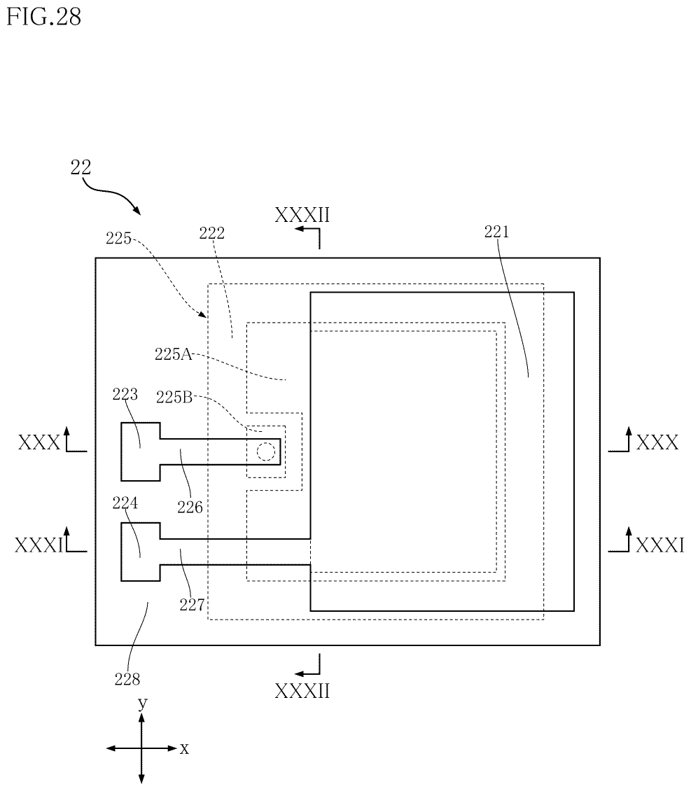

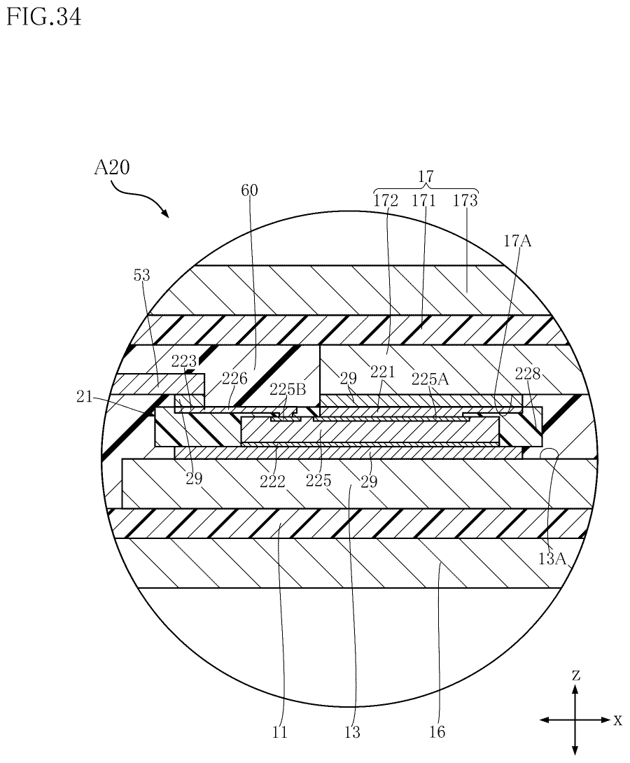

As shown in FIGS. 28 to 32, each of the second semiconductor elements 22 has a second detection electrode 224, a second element body 225, a third rewiring 226, a fourth rewiring 227, and a second resin 228. Each of the second semiconductor elements 22 is provided in a resin package. The second element body 225 is an element corresponding to one of the second semiconductor elements 22 in the semiconductor device A10. The second element body 225 includes a second pad 225A and a second gate pad 225B. As shown in FIG. 34, the second pad 225A and the second gate pad 225B are located opposite from the side facing the second conductive layer 13 in the first direction z. The second pad 225A corresponds to the third electrode 221 of the second semiconductor element 22 in the semiconductor device A10. The second gate pad 225B corresponds to the second gate electrode 223 of the second semiconductor element 22 in the semiconductor device A10. The first element body 215 includes a fourth electrode 222.

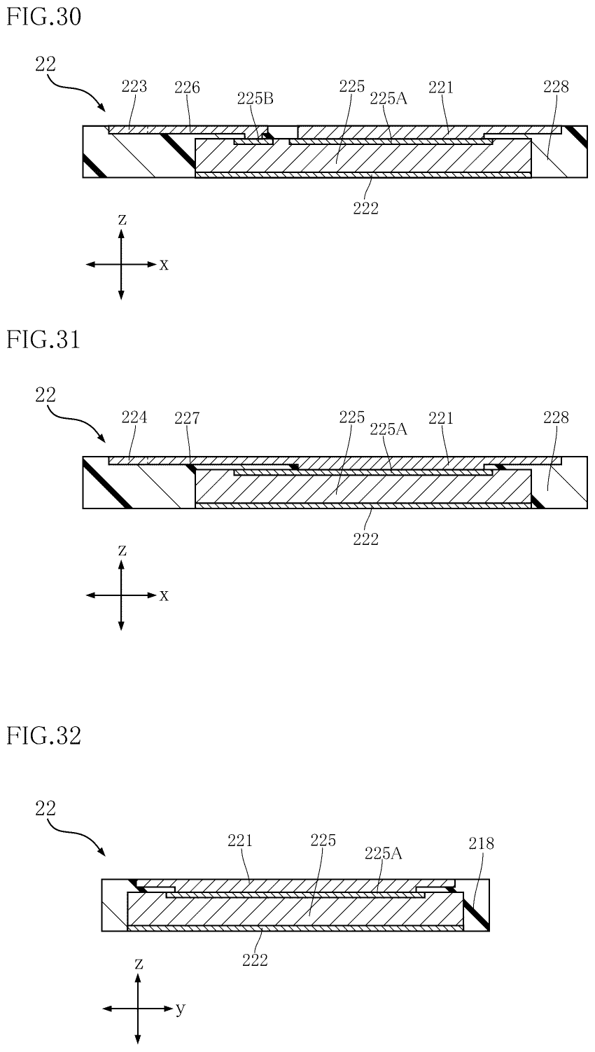

As shown in FIGS. 30 to 32, the second resin 228 covers a portion of the second element body 225 and at least a portion of each of the third rewiring 226 and the fourth rewiring 227. The third electrode 221, the fourth electrode 222, the second gate electrode 223, and the second detection electrode 224 are exposed from the second resin 228.

As shown in FIGS. 30 to 32, the third electrode 221 is electrically connected to and in contact with the second pad 225A. As shown in FIG. 28, the third electrode 221 includes a portion extending outward beyond the fourth electrode 222 as viewed in the first direction z. As viewed in the first direction z, the area of the third electrode 221 is larger than that of the second pad 225A.

As shown in FIGS. 28, 30, and 31, the second gate electrode 223 and the second detection electrode 224 are located on the same side as the third electrode 221 in the first direction z. The second detection electrode 224 is spaced apart from the second gate electrode 223 in the third direction y.

As shown in FIGS. 28 to 30, the third rewiring 226 electrically connects the second gate pad 225B of the second element body 225 and the second gate electrode 223. A portion of the third rewiring 226 is covered with the second resin 228.

As shown in FIGS. 28, 29, and 31, the fourth rewiring 227 electrically connects the second pad 225A of the second element body 225 and the second detection electrode 224. A portion of the fourth rewiring 227 is covered with the second resin 228. The fourth rewiring 227 is connected to the third electrode 221.

The third rewiring 226, the fourth rewiring 227, and the second resin 228 can be formed by the LDS process described above. In this case, the material of the second resin 228 contains an additive containing a metal element. Each of the third rewiring 226 and the fourth rewiring 227 contains the metal element.

As shown in FIG. 34, the bonding surface 17A of the third conductive 172 of the conductive member 17 is conductively bonded to the third electrode 221 of each of the second semiconductor elements 22 via a conductive bonding layer 29.

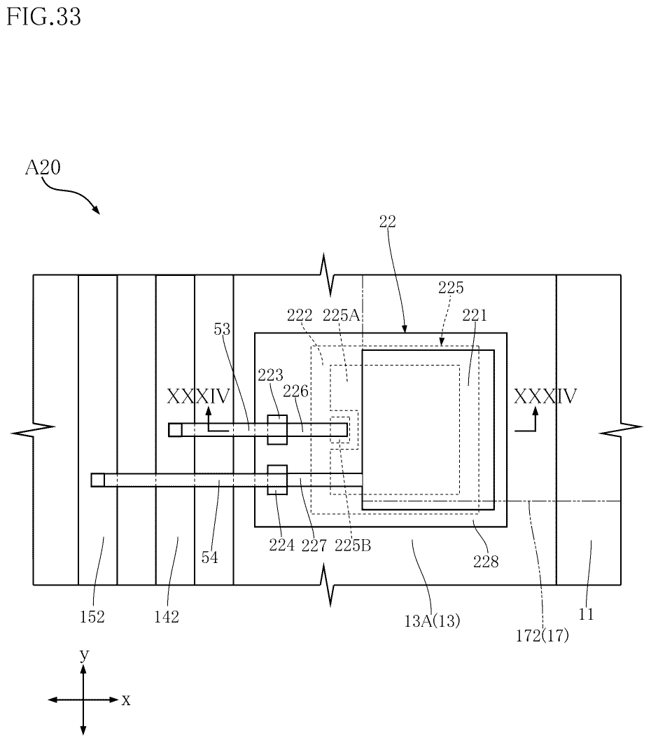

As shown in FIGS. 15 and 33, each of the second detection wirings 54 is conductively bonded to the second detection electrode 224 of one of the second semiconductor elements 22 and the second detection conductive layer 152. The second gate wirings 53 and the second detection wirings 54 are metal leads. The composition of each of the second gate wirings 53 and the second detection wirings 54 includes copper.

The following describes advantages of the semiconductor device A20.

The semiconductor device A20 includes a first insulation layer 11, a first conductive layer 12, a second conductive layer 13, a first heat dissipation layer 16, a first semiconductor element 21, a second semiconductor element 22, a conductive member 17, and a sealing resin 60. The first semiconductor element 21 has a first electrode 211 conductively bonded to the first conductive layer 12, and a second electrode 212 to which the conductive member 17 is conductively bonded. The second semiconductor element 22 has a third electrode 221 to which the conductive member 17 is conductively bonded, and a fourth electrode 222 conductively bonded to the second conductive layer 13. The polarity of the second electrode 212 is different from that of the third electrode 221. The first heat dissipation layer 16 and the conductive member 17 are exposed from the sealing resin 60. Thus, according to the configuration, it is possible to improve the heat dissipation of the semiconductor device A20 while reducing the parasitic inductance of the semiconductor device A20. Furthermore, the semiconductor device A20 has advantages similar to the semiconductor device A10 owing to its common configuration with the semiconductor device A10.

In the semiconductor device A20, the first semiconductor element 21 has the second electrode 212, a first element body 215 including a first pad 215A and a first gate pad 215B, and a first rewiring 216 electrically connecting a first gate pad 215B and a first gate electrode 213. The first gate electrode 213 is located on the same side as the second electrode 212 in the first direction z. The first electrode 211 is connected to the first pad 215A. This configuration can prevent a short circuit between the first gate electrode 213 and the first conductive layer 12 even when the first electrode 211 is conductively bonded to the first conductive layer 12 without intervention of a first spacer 31. This eliminates the need of a first spacer 31 or a second spacer 32, thus reducing the dimension of the semiconductor device A20 in the first direction z and further reducing the parasitic inductance of the semiconductor device A20.

In the above case, the second semiconductor element 22 has the fourth electrode 222, a second element body 225 including a second pad 225A and a second gate pad 225B, and a third rewiring 226 electrically connecting a second gate pad 225B and a second gate electrode 223. The second gate electrode 223 is located on the same side as the third electrode 221 in the first direction z. The third electrode 221 is in contact with the second pad 225A. This configuration allows the dimension of the second semiconductor element 22 in the first direction z to coincide with the dimension of the first semiconductor element 21 in the first direction z.

### Third Embodiment

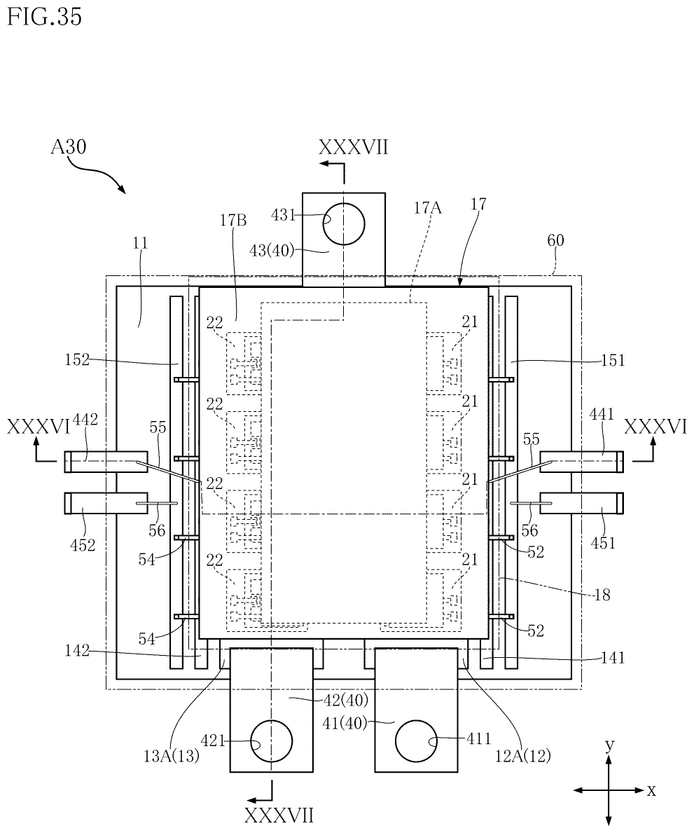

The following describes a semiconductor device A30 of a third embodiment of the present disclosure with reference to FIGS. 35 to 37. In these figures, elements that are the same as or similar to those of the semiconductor devices A10 and A20 are denoted by the same reference numerals and the descriptions thereof are omitted. For convenience of understanding, FIG. 35 shows the sealing resin 60 and a covering layer 18 (described below) as transparent. In FIG. 35, the outline of the sealing resin 60, which is shown as transparent, is indicated by an imaginary line. FIG. 35 shows lines XXXVI-XXXVI and XXXVII-XXXVII with single-dot chain lines.

The semiconductor device A30 is different from the semiconductor device A20 in the configuration of the conductive member 17 and in further including a covering layer 18.

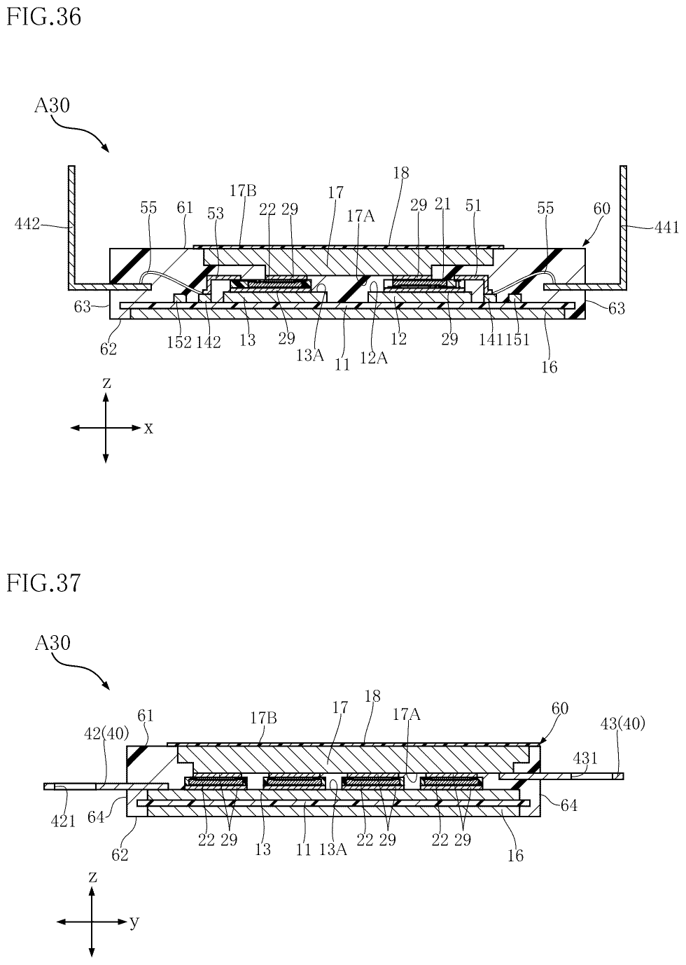

As shown in FIGS. 36 and 37, the conductive member 17 is a single member made of metal, unlike a composite member including an insulator and a conductor, such as the conductive member 17 in the semiconductor device A20. The metal contains copper, for example. The ends of the conductive member 17 in a direction perpendicular to the first direction z are each provided with a step.

As shown in FIGS. 36 and 37, the covering layer 18 covers the heat dissipation surface 17B of the conductive member 17, and is exposed to the outside. The covering layer 18 is an insulator. The sealing resin 60 is in contact with the covering layer 18.

The conductive member 17 and the covering layer 18 in the semiconductor device A30 are applicable to the semiconductor device A10 as well as the semiconductor device A20.

The following describes advantages of the semiconductor device A30.

The semiconductor device A30 includes a first insulation layer 11, a first conductive layer 12, a second conductive layer 13, a first heat dissipation layer 16, a first semiconductor element 21, a second semiconductor element 22, a conductive member 17, and a sealing resin 60. The first semiconductor element 21 has a first electrode 211 conductively bonded to the first conductive layer 12, and a second electrode 212 to which the conductive member 17 is conductively bonded. The second semiconductor element 22 has a third electrode 221 to which the conductive member 17 is conductively bonded, and a fourth electrode 222 conductively bonded to the second conductive layer 13. The polarity of the second electrode 212 is different from that of the third electrode 221. The first heat dissipation layer 16 and the conductive member 17 are exposed from the sealing resin 60. Thus, according to the configuration, it is possible to improve the heat dissipation of the semiconductor device A30 while reducing the parasitic inductance of the semiconductor device A30. Furthermore, the semiconductor device A30 has advantages similar to the semiconductor device A10 owing to its common configuration with the semiconductor device A10.

In the semiconductor device A30, the conductive member 17 is a single metal member. This configuration facilitates conduction of heat from a bonding surface 17A to a heat dissipation surface 17B of the conductive member 17, as compared to the conductive member 17 of the semiconductor device A20. This further improves the heat dissipation of the semiconductor device A30. In this case, the semiconductor device A30 includes a covering layer 18, thereby achieving the electrical insulation of the conductive member 17 from the outside.

The present disclosure is not limited to the above embodiments. Various design changes can be made to the specific configurations of the elements in the present disclosure.

The present disclosure includes the embodiments described in the following clauses.
Clause 1.
A semiconductor device comprising:
a first insulation layer;
a first conductive layer bonded to the first insulation layer on a first side in a first direction;
a second conductive layer located on a same side as the first conductive layer in the first direction and bonded to the first insulation layer;
a first heat dissipation layer located opposite from the first conductive layer and the second conductive layer with respect to the first insulation layer and bonded to the first insulation layer;
a first element including semiconductor a first electrode and a second electrode located opposite to each other in the first direction, the first electrode being conductively bonded to the first conductive layer;
a second semiconductor element including a third electrode and a fourth electrode located opposite to each other in the first direction, the fourth electrode being conductively bonded to the second conductive layer;
a conductive member conductively bonded to the second electrode and the third electrode; and
a sealing resin covering the first semiconductor element and the second semiconductor element,
wherein a polarity of the second electrode is different from a polarity of the third electrode, and the first heat dissipation layer and the conductive member are exposed from the sealing resin.
Clause 2.
The semiconductor device according to clause 1, wherein the conductive member includes a bonding surface conductively bonded to the second electrode and the third electrode, and a heat dissipation surface facing away from the bonding surface in the first direction and exposed from the sealing resin, and
an area of the heat dissipation surface is larger than an area of the bonding surface.
Clause 3.
The semiconductor device according to clause 2, wherein as viewed in the first direction, the bonding surface is surrounded by a periphery of the heat dissipation surface.
Clause 4.
The semiconductor device according to clause 2 or 3, wherein the conductive member includes a second insulation layer, a third conductive layer including the bonding surface and bonded to the second insulation layer, and a second heat dissipation layer including the heat dissipation surface and bonded to the second insulation layer, and
as viewed in the first direction, the second heat dissipation layer is surrounded by a periphery of the second insulation layer.
Clause 5.
The semiconductor device according to clause 4, wherein a thickness of each of the third conductive layer and the second heat dissipation layer is larger than a thickness of the second insulation layer.
Clause 6.
The semiconductor device according to clause 2 or 3, further comprising a covering layer that is an insulator,
wherein the covering layer covers the heat dissipation surface, and is exposed to an outside, and
the sealing resin is in contact with the covering layer.
Clause 7.
The semiconductor device according to clause 4 or 5, wherein the first semiconductor element includes a first gate electrode,
the semiconductor device further includes a first gate wiring conductively bonded to the first gate electrode, and
as viewed in the first direction, the first gate wiring overlaps with the second insulation layer.
Clause 8.
The semiconductor device according to clause 7, wherein as viewed in the first direction, the first gate wiring overlaps with the second heat dissipation layer.
Clause 9.
The semiconductor device according to clause 7 or 8, wherein the first gate electrode is located on a same side as
the first electrode in the first direction, the semiconductor device further comprises a first spacer that conductively bonds the first conductive layer and the first electrode,
the first spacer includes a first surface facing the first electrode, and
as viewed in the first direction, the first surface is spaced apart from the first gate electrode.
Clause 10.
The semiconductor device according to clause 9, wherein the first spacer includes a second surface facing the first conductive layer,
an area of the second surface is larger than an area of the first surface, and
as viewed in the first direction, the first surface is surrounded by a periphery of the second surface.
Clause 11.
The semiconductor device according to clause 7 or 8, wherein the first semiconductor element includes a first element body provided with a first pad and a first gate pad located on a side facing the first conductive layer in the first direction, and a first rewiring electrically connecting the first gate pad and the first gate electrode,
the first element body includes the second electrode,
the first gate electrode is located on a same side as the second electrode in the first direction, and
the first electrode is electrically connected to the first pad.
Clause 12.
The semiconductor device according to clause 11, wherein the first electrode is in contact with the first pad.
Clause 13.
The semiconductor device according to clause 12, wherein the first semiconductor element includes a first resin covering a portion of the first element body and at least a portion of the first rewiring, and
the first electrode, the second electrode, and the first gate electrode are exposed from the first resin.
Clause 14.
The semiconductor device according to clause 13, wherein the first semiconductor element includes a first detection electrode located on a same side as the first gate electrode in the first direction, and a second rewiring electrically connecting the first pad and the first detection electrode,
at least a portion of the second rewiring is covered with the first resin, and
the first detection electrode is exposed from the first resin.
Clause 15.
The semiconductor device according to clause 13 or 14, wherein the second semiconductor element includes a second element body including a second pad and a second gate pad located opposite from a side facing the second conductive layer in the first direction, and a second gate electrode electrically connected to the second gate pad,
the second element body includes the fourth electrode,
the second gate electrode is located on a same side as the third electrode in the first direction, and
the third electrode is in contact with the second pad.
Clause 16.
The semiconductor device according to any of clauses 1 to 15, wherein a thickness of each of the first conductive layer, the second conductive layer, and the first heat dissipation layer is larger than a thickness of the first insulation layer.
Clause 17.
The semiconductor device according to any of clauses 1 to 16, further comprising a plurality of power terminals,
wherein each of the plurality of power terminals is electrically connected to one of the first conductive layer, the second conductive layer, and the conductive member.

REFERENCE NUMERALS

| | |
|---|---|
| A10, A20, A30: | Semiconductor device |
| 11: | First insulation layer |
| 12: | First conductive layer |
| 12A: | First obverse surface |
| 13: | Second conductive layer |
| 13A: | Second obverse surface |
| 141: | First gate conductive layer |
| 142: | Second gate conductive layer |
| 151: | First detection conductive layer |
| 152: | Second detection conductive layer |
| 16: | First heat dissipation layer |
| 17: | Conductive member |
| 17A: | Bonding surface |
| 17B: | Heat dissipation surface |
| 171: | Second insulation layer |
| 172: | Third conductive layer |
| 173: | Second heat dissipation layer |
| 18: | Covering layer |
| 21: | First semiconductor element |
| 211: | First electrode |
| 212: | Second electrode |
| 213: | First gate electrode |
| 214: | First detection electrode |
| 215: | First element body |
| 215A: | First pad |
| 215B: | First gate pad |
| 216: | First rewiring |
| 217: | Second rewiring |
| 218: | First resin |
| 219: | Covering layer |
| 22: | Second semiconductor element |
| 221: | Third electrode |
| 222: | Fourth electrode |
| 223: | Second gate electrode |
| 224: | Second detection electrode |
| 225: | Second element body |
| 225A: | Second pad |
| 225B: | Second gate pad |
| 226: | Third rewiring |
| 227: | Fourth rewiring |
| 228: | Second resin |
| 29: | Conductive bonding layer |
| 31: | First spacer |
| 311: | First portion |
| 311A: | Second surface |
| 312A: | Third surface |
| 313A: | Fourth surface |
| 314A: | First recess |
| 312: | Second portion |
| 312A: | First surface |
| 312B: | Second recess |
| 32: | Second spacer |
| 40: | Power terminal |
| 41: | First input terminal |
| 411: | First mounting hole |
| 42: | Second input terminal |
| 421: | Second mounting hole |
| 43: | Output terminal |
| 431: | Third mounting hole |
| 441: | First gate terminal |
| 442: | Second gate terminal |
| 451: | First detection terminal |
| 452: | Second detection terminal |
| 51: | First gate wiring |
| 52: | First detection wiring |
| 53: | Second gate wiring |
| 54: | Second detection wiring |
| 55: | First wire |
| 56: | Second wire |
| 60: | Sealing resin |
| 61: | Top surface |
| 62: | Bottom surface |
| 63: | First side surface |
| 64: | Second side surface |
| z: | First direction |
| x: | Second direction |
| y: | Third direction |

1. A semiconductor device comprising:
a first insulation layer;
a first conductive layer bonded to the first insulation layer on a first side in a first direction;
a second conductive layer located on a same side as the first conductive layer in the first direction and bonded to the first insulation layer;
a first heat dissipation layer located opposite from the first conductive layer and the second conductive layer with respect to the first insulation layer and bonded to the first insulation layer;
a first semiconductor element including a first electrode and a second electrode located opposite to each other in the first direction, the first electrode being conductively bonded to the first conductive layer;
a second semiconductor element including a third electrode and a fourth electrode located opposite to each other in the first direction, the fourth electrode being conductively bonded to the second conductive layer;
a conductive member conductively bonded to the second electrode and the third electrode; and
a sealing resin covering the first semiconductor element and the second semiconductor element,
wherein a polarity of the second electrode is different from a polarity of the third electrode, and
the first heat dissipation layer and the conductive member are exposed from the sealing resin.

2. The semiconductor device according to claim 1, wherein the conductive member includes a bonding surface conductively bonded to the second electrode and the third electrode, and a heat dissipation surface facing away from the bonding surface in the first direction and exposed from the sealing resin, and
an area of the heat dissipation surface is larger than an area of the bonding surface.

3. The semiconductor device according to claim 2, wherein as viewed in the first direction, the bonding surface is surrounded by a periphery of the heat dissipation surface.

4. The semiconductor device according to claim 2, wherein the conductive member includes a second insulation layer, a third conductive layer including the bonding surface and bonded to the second insulation layer, and a second heat dissipation layer including the heat dissipation surface and bonded to the second insulation layer, and
as viewed in the first direction, the second heat dissipation layer is surrounded by a periphery of the second insulation layer.

5. The semiconductor device according to claim 4, wherein a thickness of each of the third conductive layer and the second heat dissipation layer is larger than a thickness of the second insulation layer.

6. The semiconductor device according to claim 2, further comprising a covering layer that is an insulator,
wherein the covering layer covers the heat dissipation surface, and is exposed to an outside, and
the sealing resin is in contact with the covering layer.

7. The semiconductor device according to claim 4, wherein the first semiconductor element includes a first gate electrode,
the semiconductor device further includes a first gate wiring conductively bonded to the first gate electrode, and
as viewed in the first direction, the first gate wiring overlaps with the second insulation layer.

8. The semiconductor device according to claim 7, wherein as viewed in the first direction, the first gate wiring overlaps with the second heat dissipation layer.

9. The semiconductor device according to claim 7, wherein the first gate electrode is located on a same side as the first electrode in the first direction,
the semiconductor device further comprises a first spacer that conductively bonds the first conductive layer and the first electrode,
the first spacer includes a first surface facing the first electrode, and
as viewed in the first direction, the first surface is spaced apart from the first gate electrode.

10. The semiconductor device according to claim 9, wherein the first spacer includes a second surface facing the first conductive layer,
an area of the second surface is larger than an area of the first surface, and
as viewed in the first direction, the first surface is surrounded by a periphery of the second surface.

11. The semiconductor device according to claim 7, wherein the first semiconductor element includes a first element body provided with a first pad and a first gate pad located on a side facing the first conductive layer in the first direction, and a first rewiring electrically connecting the first gate pad and the first gate electrode,
the first element body includes the second electrode,
the first gate electrode is located on a same side as the second electrode in the first direction, and
the first electrode is electrically connected to the first pad.

12. The semiconductor device according to claim 11, wherein the first electrode is in contact with the first pad.

13. The semiconductor device according to claim 12, wherein the first semiconductor element: includes a first resin covering a portion of the first element body and at least a portion of the first rewiring, and
the first electrode, the second electrode, and the first gate electrode are exposed from the first resin.

14. The semiconductor device according to claim 13, wherein the first semiconductor element includes a first detection electrode located on a same side as the first gate electrode in the first direction, and a second rewiring electrically connecting the first pad and the first detection electrode,
at least a portion of the second rewiring is covered with the first resin, and
the first detection electrode is exposed from the first resin.

15. The semiconductor device according to claim 13, wherein the second semiconductor element includes a second element body including a second pad and a second gate pad located opposite from a side facing the second conductive layer in the first direction, and a second gate electrode electrically connected to the second gate pad,
the second element body includes the fourth electrode,
the second gate electrode is located on a same side as the third electrode in the first direction, and
the third electrode is in contact with the second pad.

16. The semiconductor device according to claim 1, wherein a thickness of each of the first conductive layer, the second conductive layer, and the first heat dissipation layer is larger than a thickness of the first insulation layer.

17. The semiconductor device according to claim 1, further comprising a plurality of power terminals,
wherein each of the plurality of power terminals is electrically connected to one of the first conductive layer, the second conductive layer, and the third conductive layer.
